(19) United States
(12) Patent Application Publication
(10) Pub. No.: US 2026/0182177 A1
(43) Pub. Date: Jun. 25, 2026

(54) Display Substrate, Manufacturing Method Therefor, and Display Apparatus

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Tao HAN, Beijing (CN); Yao HUANG, Beijing (CN); Yu WANG, Beijing (CN); Jun YAN, Beijing (CN); Kemeng TONG, Beijing (CN); Yi HE, Beijing (CN)

(21) Appl. No.: 18/850,069

(22) PCT Filed: Sep. 26, 2023
(86) PCT No.: PCT/CN2023/121725

§ 371 Date: Sep. 24, 2024

(51) Int. Cl. H10K 59/131; H10K 59/12; H10K 59/121

(52) U.S. Cl. CPC H10K 59/131; H10K 59/1201; H10K 59/1213

(57) ABSTRACT

A display substrate includes a display area, wherein the display area includes a plurality of circuit units, a circuit unit includes a pixel drive circuit and at least one signal line transmitting a constant voltage signal, the pixel drive circuit includes at least one pixel transistor; in a direction perpendicular to the display substrate, the display substrate at least includes a first semiconductor layer arranged on a substrate and a second semiconductor layer arranged on a side of the first semiconductor layer away from the substrate.

### CROSS-REFERENCE TO RELATED APPLICATION

This application is a national stage application of PCT Application No. PCT/CN2023/121725, which is filed on Sep. 26, 2023 and entitled “Display Substrate, Manufacturing Method Therefor, and Display Apparatus”, the content of which should be regarded as being incorporated herein by reference.

### TECHNICAL FIELD

The present disclosure relates to, but is not limited to, the field of display technologies, and particularly to a display substrate and a manufacturing method therefor, and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matters described herein in detail. This summary is not intended to limit the protection scope of claims.

In one aspect, the present disclosure provides a display substrate, including a display area, wherein the display area includes a plurality of circuit units constituting a plurality of unit rows and a plurality of unit columns, at least one circuit unit includes a pixel drive circuit and at least one signal line transmitting a constant voltage signal, the pixel drive circuit includes at least one pixel transistor; in a direction perpendicular to the display substrate, the display substrate at least includes a first semiconductor layer arranged on a substrate and a second semiconductor layer arranged on a side of the first semiconductor layer away from the substrate; and in at least one circuit unit, one of the first semiconductor layer and the second semiconductor layer includes at least one semiconductor line, and the other includes an active layer of the pixel transistor, and the semiconductor line is connected to the signal line.

In an exemplary implementation, in at least one circuit unit, the at least one semiconductor line includes a first semiconductor line and a second semiconductor line extending in a pixel row direction, and a third semiconductor line extending in a pixel column direction, and the first semiconductor line and the second semiconductor line are connected to the third semiconductor line to form a mesh communication structure.

In an exemplary implementation, in at least one circuit unit, the at least one signal line includes a first power supply connection line extending in the pixel row direction and a first power supply line extending in the pixel column direction, the first power supply connection line is connected to the first power supply line to form a mesh communication structure, and the first power supply connection line is connected to the first semiconductor line.

In an exemplary implementation, an orthographic projection of the first power supply connection line on the substrate overlaps at least partially with an orthographic projection of the first semiconductor line on the substrate.

In an exemplary implementation, in a direction perpendicular to the display substrate, the display substrate further includes a plurality of conductive layers, the first power supply connection line and the first power supply line are arranged in different conductive layers, the first power supply line is connected to the first power supply connection line through a via, and the first power supply connection line is connected to the first semiconductor line through a via.

In an exemplary implementation, in at least one circuit unit, the at least one signal line includes a second power supply connection line extending in the pixel row direction and a second power supply line extending in the pixel column direction, the second power supply connection line is connected to the second power supply line to form a mesh communication structure; and an orthographic projection of the second power supply line on the substrate overlaps at least partially with an orthographic projection of the third semiconductor line on the substrate.

In an exemplary implementation, in at least one circuit unit, the at least one signal line includes a first initial signal line extending in the pixel row direction and a first initial connection line extending in the pixel column direction, the first initial connection line is connected to the first initial signal line to form a mesh communication structure; and an orthographic projection of the first initial connection line on the substrate overlaps at least partially with the orthographic projection of the third semiconductor line on the substrate.

In an exemplary implementation, an orthographic projection of the first initial signal line on the substrate overlaps at least partially with an orthographic projection of the second semiconductor line on the substrate.

In an exemplary implementation, in at least one circuit unit, the at least one signal line includes a second initial signal line extending in the pixel row direction and a second initial connection line extending in the pixel column direction, the second initial connection line is connected to the second initial signal line to form a mesh communication structure; and an orthographic projection of the second initial connection line on the substrate overlaps at least partially with the orthographic projection of the third semiconductor line on the substrate.

In an exemplary implementation, the pixel drive circuit further includes a storage capacitor including a first electrode plate and a second electrode plate, an orthographic projection of the first electrode plate on the substrate overlaps at least partially with an orthographic projection of the second electrode plate on the substrate, the orthographic projection of the first electrode plate on the substrate does not overlap with an orthographic projection of the semiconductor line on the substrate, and the orthographic projection of the second electrode plate on the substrate does not overlap with the orthographic projection of the semiconductor line on the substrate.

In an exemplary implementation, a material of the first semiconductor layer includes polysilicon, a material of the second semiconductor layer includes an oxide, the first semiconductor layer includes the semiconductor lines, and the second semiconductor layer includes the active layer of the pixel transistor.

In an exemplary implementation, the display substrate further includes a bezel area arranged on at least one side of the display area, the bezel area includes a plurality of gate units, at least one gate unit includes a gate drive circuit including a plurality of gate transistors, and active layers of the gate transistors and the semiconductor lines are arranged in a same layer and made of a same material.

In an exemplary implementation, in a direction parallel to the display substrate, the circuit unit has a first unit area, in at least one circuit unit, an orthographic projection of the semiconductor line on the substrate has a first area, and a ratio of the first area to the first unit area has a first ratio value which is 0.1 to 0.2.

In an exemplary implementation, in a direction parallel to the display substrate, the gate unit has a second unit area, in at least one gate unit, orthographic projections of the active layers of the plurality of gate transistors on the substrate have a second area, a ratio of the second area to the second unit area has a second ratio value, and a ratio of the first ratio value to the second ratio value is 0.9 to 1.1.

In an exemplary implementation, the bezel area further includes a semiconductor lead extending in a direction of a display area edge and connected to the semiconductor lines in a plurality of unit rows, and the display area edge is an edge of the display area close to the bezel area.

In an exemplary implementation, the semiconductor lead and the semiconductor line are arranged in a same layer and are connected to each other to form an integrated structure.

In another aspect, the present disclosure also provides a display apparatus, including the display substrate described above.

In a further aspect, the present disclosure further provides a method for manufacturing a display substrate, wherein the display substrate includes a display area, the display area includes a plurality of circuit units constituting a plurality of unit rows and a plurality of unit columns, at least one circuit unit includes a pixel drive circuit and at least one signal line transmitting a constant voltage signal, the pixel drive circuit includes at least one pixel transistor; the method including:
forming a first semiconductor layer on a substrate and a second semiconductor layer arranged on a side of the first semiconductor layer away from the substrate, wherein in at least one circuit unit, one of the first semiconductor layer and the second semiconductor layer includes at least one semiconductor line, and the other includes an active layer of the pixel transistor, and the semiconductor line is connected to the signal line.

Other aspects of the present disclosure may be comprehended after the drawings and the detailed descriptions are read and understood.

### BRIEF DESCRIPTION OF DRAWINGS

Accompany drawings are used to provide understanding of technical solution of the present disclosure, and form a part of the specification. The accompany drawings and embodiments of the present disclosure are adopted to explain the technical solution of the present disclosure, and do not form limitations on the technical solution of the present disclosure.

FIG. 1 is a schematic diagram of a structure of a display apparatus.

FIG. 2 is a schematic diagram of a structure of a display substrate.

FIG. 3 is a schematic diagram of a planar structure of a display area in a display substrate.

FIG. 4 is a schematic diagram of a sectional structure of a display area in a display substrate.

FIG. 5 is an equivalent circuit diagram of a pixel drive circuit according to an exemplary embodiment of the present disclosure.

FIG. 6 is a schematic diagram of a planar structure of a display area in a display substrate according to an exemplary embodiment of the present disclosure.

FIG. 7 is a schematic diagram of a structure of a signal line of a network communication structure according to an exemplary embodiment of the present disclosure.

FIG. 8 is a schematic diagram of a display substrate after a pattern of a first semiconductor layer is formed according to the present disclosure.

FIG. 9A and FIG. 9B are schematic diagrams of a display substrate after a pattern of a first conductive layer is formed according to the present disclosure.

FIGS. 10A and 10B are schematic diagrams of a display substrate after a pattern of a second conductive layer is formed according to the present disclosure.

FIG. 11A and FIG. 11B are schematic diagrams of a display substrate after a pattern of a second semiconductor layer is formed according to the present disclosure.

FIG. 12A and FIG. 12B are schematic diagrams of a display substrate after a pattern of a third conductive layer is formed according to the present disclosure.

FIG. 13 is a schematic diagram of a display substrate after a pattern of a sixth insulating layer is formed according to the present disclosure.

FIG. 14A and FIG. 14B are schematic views of a display substrate after a pattern of a fourth conductive layer is formed according to the present disclosure.

FIG. 15 is a schematic diagram of a display substrate after a pattern of a first planarization layer is formed according to the present disclosure.

FIG. 16A and FIG. 16B are schematic diagrams of a display substrate after a pattern of a fifth conductive layer is formed according to the present disclosure.

FIG. 17 is a schematic diagram of a semiconductor wire in a bezel area according to an exemplary embodiment of the present disclosure.

Reference signs are described as follows.

11—first semiconductor line; 12—second semiconductor line; 13—third semiconductor line; 21—first bottom gate electrode; 22—second bottom gate electrode; 24—fourth bottom gate electrode; 25—fifth bottom gate electrode; 31—first active layer; 32—second active layer; 33—third active layer; 34—fourth active layer; 35—fifth active layer; 41—first top gate electrode; 42—second top gate electrode; 43—third gate electrode; 44—fourth top gate electrode; 45—fifth top gate electrode; 51—first connection electrode; 52—second connection electrode; 53—third connection electrode; 61—first power supply connection line; 62—second power supply connection line; 63—first initial signal line; 64—second initial signal line; 71—first scan signal line; 72—second scan signal line; 73—third scan signal line; 74—light emitting signal line; 81—first power supply line; 82—second power supply line; 83—first initial connection line; 84—second initial connection line; 85—data signal line; 86—anode connection electrode; 91—first electrode plate; 92—second electrode plate; 100—display area; 101—substrate; 102—drive circuit layer; 103—light emitting structure layer; 104—encapsulation structure layer; 200—bonding area; 300—bezel area; 301—gate active layer; 310—semiconductor wire.

### DETAILED DESCRIPTION

To make the objectives, technical solutions, and advantages of the present disclosure clearer, the embodiments of the present disclosure will be described in detail below with reference to the accompany drawings. It is to be noted that implementation modes may be implemented in multiple different forms. Those of ordinary skills in the art can easily understand such a fact that implementation modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “electrical connection” includes connection of composition elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive thin film” sometimes. Similarly, an “insulation film” may be replaced with an “insulation layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc. In the present disclosure, “about” refers to that a boundary is not defined so strictly and numerical values within a range of process and measurement errors are allowed.

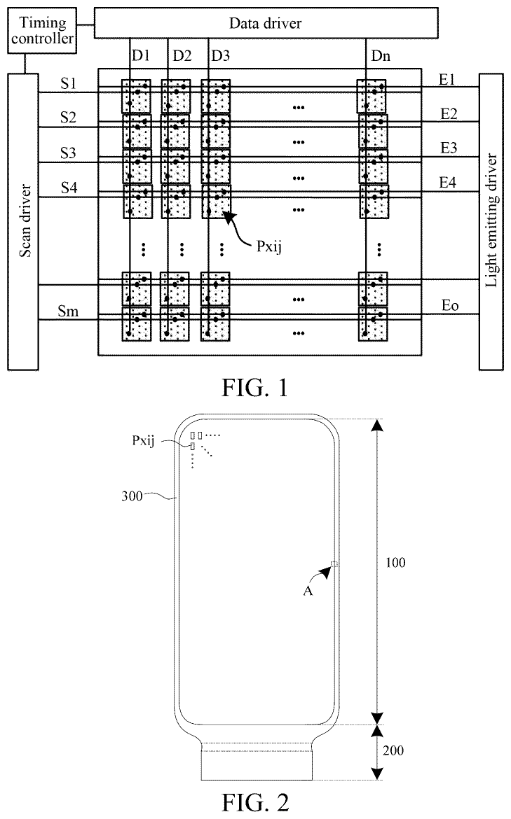

FIG. 1 is a schematic diagram of a structure of a display apparatus. As shown in FIG. 1, the display apparatus may include a timing controller, a data driver, a scan driver, a light emitting driver, and a pixel array. The timing controller is connected to the data driver, the scan driver, and the light emitting driver, respectively, the data driver is connected to a plurality of data signal lines (D1 to Dn) respectively, the scan driver is connected to a plurality of scan signal lines (S1 to Sm) respectively, and the light emitting driver is connected to a plurality of light emitting signal lines (E1 to Eo) respectively. The pixel array may include a plurality of sub-pixels Pxij, i and j may be natural numbers, at least one sub-pixel Pxij may include a circuit unit and a light emitting unit, the circuit unit may include, at least, a pixel drive circuit connected to a scan signal line, a light emitting signal line and a data signal line, respectively. The light emitting unit may include a light emitting device connected to the pixel drive circuit of the circuit unit. In an exemplary implementation, the timing controller may provide the data driver with a gray scale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the gray scale value using the clock signal and apply a data voltage corresponding to the gray scale value to the data signal lines D1 to Dn by taking a pixel row as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation, the pixel array may be disposed on the display substrate.

FIG. 2 is a schematic diagram of a structure of a display substrate. As shown in FIG. 2, the display substrate may include a display area 100, a bonding area 200 located on a side of the display area 100, and a bezel area 300 located on another side of the display area 100. In an exemplary implementation, the display area 100 may be a planar region including a plurality of sub-pixels Pxij that form a pixel array, the plurality of sub-pixels Pxij are configured to display a dynamic picture or a static image, and the display area 100 may be referred to as an Active Area (AA). In an exemplary implementation, the display substrate may be deformable, e.g., may be crimped, bent, folded, or curled.

In an exemplary implementation, the bonding area 200 may include a fan-out region, a bending region, a drive chip region, and a bonding pin region that are disposed sequentially along a direction away from the display area 100. The fan-out region is connected to the display area 100 and may at least include a plurality of data fan-out lines. A plurality of data fan-out lines are configured to be connected to data signal lines of the display area in a fan-out wiring manner. The bending region is arranged on a side of the fan-out region away from the display area, and may include a composite insulating layer provided with grooves configured to bend the bonding area to the back of the display area. The drive chip region is arranged on a side of the bending region away from the display area, and may at least include an Integrated Circuit (IC) configured to be connected to a plurality of data fan-out lines. The bonding pin region is arranged on a side of the drive chip area away from the display area, and may at least include a plurality of binding pins (Bonding Pads) configured to be bonding-connected to an external Flexible Printed Circuit (FPC).

In an exemplary implementation, the bezel area 300 may at least include a circuit region, a power supply line region, a crack dam region and a cutting region which are arranged sequentially in a direction away from the display area 100. The circuit region may include a plurality of gate units, and a gate unit may include a gate drive circuit connected to a scan signal line and a light emitting signal line in the display area 100. The power supply line region is arranged on a side of the circuit region away from the display area, and may at least include a bezel power supply wire which may be connected to a cathode of a light emitting device in the display area 100. The crack dam region is arranged on a side of the power supply line region away from the display area, and may at least include a plurality of cracks provided on the composite insulating layer. The cutting region is arranged on a side of the crack dam region away from the display area, and may at least include a cutting groove provided on the composite insulating layer, and the cutting groove is configured such that a cutting device implements cutting along the cutting groove after all film layers of the display substrate are manufactured.

In an exemplary implementation, the fan-out region in the bonding area 200 and the power supply line region in the bezel area 300 may be provided with at least one dam spacer which may extend in a direction parallel to an edge of the display area to form an annular structure surrounding the display area 100.

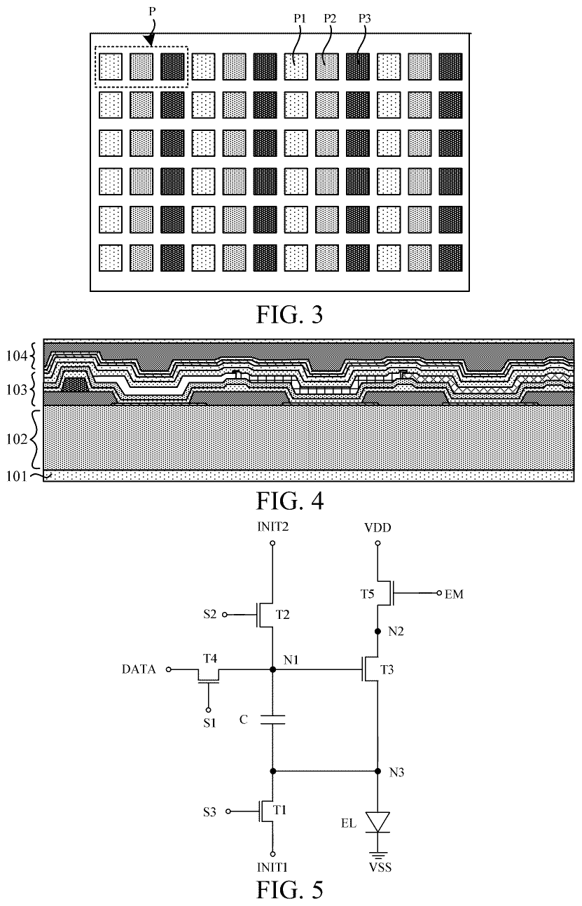

FIG. 3 is a schematic diagram of a planar structure of a display area in a display substrate. As shown in FIG. 3, the display area may include a plurality of pixel units P arranged in a matrix, and at least one of the pixel units P may include a first sub-pixel P1, a second sub-pixel P2 and a third sub-pixel P3. Each sub-pixel may include both a circuit unit and a light emitting unit. The circuit unit may at least include a pixel drive circuit. The pixel drive circuit is connected to a scan signal line, a light emitting signal line and a data signal line, and is configured to receive a data voltage transmitted by the data signal line and output a corresponding current to the light emitting unit under control of the scan signal line and the light emitting signal line. The light emitting unit may include a light emitting device connected to a pixel drive circuit of a sub-pixel where the light emitting device is located, and the light emitting device is configured to emit light of a corresponding brightness in response to the current output by the pixel drive circuit of the sub-pixel where the light emitting device is located.

In an exemplary implementation, the first sub-pixel P1 may be a red sub-pixel (R) emitting red light, the second sub-pixel P2 may be a green sub-pixel (G) emitting green light, and the third sub-pixel P3 may be a blue sub-pixel (B) emitting blue light. In an exemplary implementation, a sub-pixel may be in a shape of a rectangle, a rhombus, a pentagon, or a hexagon. Three sub-pixels may be arranged in a manner to stand side by side horizontally, in a manner to stand side by side vertically, or in a delta-shaped arrangement, etc., which is not limited here in the present disclosure.

In an exemplary implementation, a pixel unit may include four sub-pixels, and the four sub-pixels may be arranged in a manner to stand side by side horizontally, in a manner to stand side by side vertically, or in a manner of a square, which is not limited here in the present disclosure.

FIG. 4 is a schematic diagram of a sectional structure of a display area in a display substrate, illustrating a structure of three sub-pixels in the display area. As shown in FIG. 4, on a plane perpendicular to the display substrate, the display substrate may include a drive circuit layer 102 disposed on a substrate 101, a light emitting structure layer 103 disposed at a side of the drive circuit layer 102 away from the substrate 101, and an encapsulation structure layer 104 disposed at a side of the light emitting structure layer 103 away from the substrate 101. In some possible implementations, the display substrate may include another film layer, such as a touch structure layer, which is not limited here in the present disclosure.

In an exemplary implementation, the substrate 101 may be a flexible substrate, or may be a rigid substrate. The drive circuit layer 102 may include a plurality of circuit units, each of which may at least include a pixel drive circuit composed of a plurality of transistors and a storage capacitor. The light emitting structure layer 103 may include a plurality of light emitting units, each light emitting unit may include a light emitting device, and the light emitting device may at least include an anode, an organic emitting layer and a cathode. The anode is connected to a pixel drive circuit. The organic emitting layer is connected to the anode. The cathode is connected to the organic emitting layer. The organic emitting layer emits light of a corresponding color under driving of the anode and the cathode. The encapsulation structure layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is arranged between the first encapsulation layer and the third encapsulation layer to form a laminated structure of inorganic material/organic material/inorganic material and ensure that external moisture cannot enter the light emitting structure layer 103.

An exemplary embodiment of the present disclosure provides a display substrate which may include a display area and a bezel area located on at least one side of the display area. On a plane perpendicular to the display substrate, the display substrate may include a drive structure layer arranged on a substrate and a light emitting structure layer arranged on a side of the drive structure layer away from the substrate. On a plane parallel to the display substrate, the drive structure layer of the display area may include a plurality of circuit units constituting a plurality of unit rows and a plurality of unit columns, and at least one circuit unit may include a pixel drive circuit configured to output a corresponding current to a light emitting device connected to the pixel drive circuit. The drive structure layer of the bezel area may include a plurality of gate units extending in a direction parallel to a display area edge. At least one gate unit may include a gate drive circuit configured to provide a scan signal to a scan signal line in the display area. The display area edge is an edge on a side of the display area close to the bezel area. The light emitting structure layer may be arranged in the display area, and include a plurality of light emitting units. At least one light emitting unit may include a light emitting device. The light emitting device is connected to a pixel drive circuit of a corresponding circuit unit, and configured to emit light with corresponding brightness in response to a current output by the connected pixel drive circuit.

In an exemplary implementation, the circuit units mentioned in the present disclosure refer to regions divided according to pixel drive circuits, and the light emitting units mentioned in the present disclosure refer to regions divided according to light emitting devices. In an exemplary implementation, a position and shape of an orthographic projection of a light emitting unit on the substrate may correspond to a position and shape of an orthographic projection of a circuit unit on the substrate, or the position and shape of the orthographic projection of the light emitting unit on the substrate may not correspond to the position and shape of the orthographic projection of the circuit unit on the substrate.

An exemplary embodiment of the present disclosure provides a display substrate, including a display area, wherein the display area includes a plurality of circuit units constituting a plurality of unit rows and a plurality of unit columns, at least one circuit unit includes a pixel drive circuit and at least one signal line transmitting a constant voltage signal, the pixel drive circuit includes at least one pixel transistor; in a direction perpendicular to the display substrate, the display substrate at least includes a first semiconductor layer arranged on a substrate and a second semiconductor layer arranged on a side of the first semiconductor layer away from the substrate; and in at least one circuit unit, one of the first semiconductor layer and the second semiconductor layer includes at least one semiconductor line, and the other includes an active layer of the pixel transistor, and the semiconductor line is connected to the signal line.

In an exemplary implementation, in at least one circuit unit, the at least one semiconductor line includes a first semiconductor line and a second semiconductor line extending in a pixel row direction, and a third semiconductor line extending in a pixel column direction, and the first semiconductor line and the second semiconductor line are connected to the third semiconductor line to form a mesh communication structure.

In an exemplary implementation, in at least one circuit unit, the at least one signal line includes a first power supply connection line extending in the pixel row direction and a first power supply line extending in the pixel column direction, the first power supply connection line is connected to the first power supply line to form a mesh communication structure, the first power supply connection line is connected to the first semiconductor line, and an orthographic projection of the first power supply connection line on the substrate overlaps at least partially with an orthographic projection of the first semiconductor line on the substrate.

In an exemplary implementation, in at least one circuit unit, the at least one signal line includes a second power supply connection line extending in the pixel row direction and a second power supply line extending in the pixel column direction, the second power supply connection line is connected to the second power supply line to form a mesh communication structure; and an orthographic projection of the second power supply line on the substrate overlaps at least partially with an orthographic projection of the third semiconductor line on the substrate.

In an exemplary implementation, in at least one circuit unit, the at least one signal line includes a first initial signal line extending in the pixel row direction and a first initial connection line extending in the pixel column direction, the first initial connection line is connected to the first initial signal line to form a mesh communication structure; an orthographic projection of the first initial connection line on the substrate overlaps at least partially with the orthographic projection of the third semiconductor line on the substrate, and an orthographic projection of the first initial signal line on the substrate overlaps at least partially with an orthographic projection of the second semiconductor line on the substrate.

In an exemplary implementation, in at least one circuit unit, the at least one signal line includes a second initial signal line extending in the pixel row direction and a second initial connection line extending in the pixel column direction, the second initial connection line is connected to the second initial signal line to form a mesh communication structure; and an orthographic projection of the second initial connection line on the substrate overlaps at least partially with the orthographic projection of the third semiconductor line on the substrate.

In an exemplary implementation, the display substrate further includes a bezel area arranged on at least one side of the display area, the bezel area includes a plurality of gate units, at least one gate unit includes a gate drive circuit including a plurality of gate transistors, and active layers of the plurality of gate transistors and the semiconductor lines are arranged in a same layer, made of a same material, and formed synchronously by a same patterning process.

In an exemplary implementation, the bezel area further includes a semiconductor lead extending in a direction of a display area edge and connected to the semiconductor lines in a plurality of unit rows, and the display area edge is an edge of the display area close to the bezel area.

In an exemplary implementation, the semiconductor lead and the semiconductor line are arranged in a same layer and made of a same material, and are connected to each other to form an integrated structure.

The display substrate of the present embodiment will now be described through some examples.

FIG. 5 is an equivalent circuit diagram of a pixel drive circuit according to an exemplary embodiment of the present disclosure. In an exemplary implementation, the pixel drive circuit may have a structure of 3T1C, 4T1C, 5T1C, 5T2C, 6T1C, 7T1C, or 8T1C. As shown in FIG. 5, the pixel drive circuit according to an exemplary embodiment of the present disclosure may include five transistors (a first transistor T1 to a fifth transistor T5) and one storage capacitor C, and the pixel drive circuit is connected to eight signal lines (a first scan signal line S1, a second scan signal line S2, a third scan signal line S3, a light emitting signal line EM, a first initial signal line INIT1, a second initial signal line INIT2, a data signal line DATA and a first power supply line VDD).

In an exemplary implementation, the pixel drive circuit may include a first node N1, a second node N2, and a third node N3. The first node N1 is connected to a second electrode of the second transistor T2, a gate electrode of the third transistor T3, a second electrode of the fourth transistor T4 and a first terminal of the storage capacitor C, the second node N2 is connected to a first electrode of the third transistor T3 and a second electrode of the fifth transistor T5, the third node N3 is connected to a second electrode of the first transistor T1, a second electrode of the third transistor T3, and a second terminal of the storage capacitor C, and the third node N3 is also connected to a first electrode of the light emitting device EL.

In an exemplary implementation, the first terminal of the storage capacitor C is connected to the first node N1, and the second terminal of the storage capacitor C is connected to the third node N3.

In an exemplary implementation, the gate electrode of the first transistor T1 is connected to the third scan signal line S3, the first electrode of the first transistor T1 is connected to the first initial signal line INIT1, and the second electrode of the first transistor T1 is connected to the third node N3. When a turn-on signal is applied to the third scan signal line S3, the first transistor T1 is turned on, and a first initial signal is transmitted to the second terminal of the storage capacitor C and the first electrode of the light emitting device EL, thereby realizing initialization of the storage capacitor C and the light emitting device EL.

In an exemplary implementation, the gate electrode of the second transistor T2 is connected to the second scan signal line S2, the first electrode of the second transistor T2 is connected to the second initial signal line INIT2, and the second electrode of the second transistor T2 is connected to the first node N1. When a turn-on signal is applied to the second scan signal line S2, the second transistor T2 is turned on to transmit a second initial signal to the first node N1.

In an exemplary implementation, the gate electrode of the third transistor T3 is connected to the first node N1, the first electrode of the third transistor T3 is connected to the second node N2, and the second electrode of the third transistor T3 is connected to the third node N3. The third transistor T3 may be referred to as a drive transistor, and the third transistor T3 determines a size of a drive current flowing between the first power supply line VDD and the light emitting device EL according to a potential difference between the gate electrode and the first electrode of the third transistor T3.

In an exemplary implementation, the gate electrode of the fourth transistor T4 is connected to the first scan signal line S1, the first electrode of the fourth transistor T4 is connected to the data signal line DATA, and the second electrode of the fourth transistor T4 is connected to the first node N1. When a turn-on signal is applied to the first scan signal line S1, the fourth transistor T4 is turned on to transmit and input a data voltage to the first node N1.

In an exemplary implementation, the gate electrode of the fifth transistor T5 is connected to the light emitting signal line EM, the first electrode of the fifth transistor T5 is connected to the first power supply line VDD, and the second electrode of the fifth transistor T5 is connected to the second node N2. When a turn-on signal is applied to the light emitting signal line EM, the fifth transistor T5 is turned on, and a drive current path is formed between the first power supply line VDD and the light emitting device EL to enable the light emitting device EL to emit light.

In an exemplary implementation, the first electrode of the light emitting device EL is connected to the third node N3, and the second electrode of the light emitting device EL is connected to the second power supply line VSS. The light emitting device EL may be an OLED including a first electrode (anode), an organic emitting layer and a second electrode (cathode) which are stacked, or may be a QLED including a first electrode (anode), a quantum dot emitting layer and a second electrode (cathode) which are stacked.

In an exemplary implementation, the first power supply line VDD is configured to continuously provide a constant first power supply signal to the pixel drive circuit, the second power supply line VSS is configured to continuously provide a constant second power supply signal to the light emitting device EL, and the voltage of the first power supply signal is greater than the voltage of the second power supply signal. The first initial signal line INIT1 and the second initial signal line INIT2 are configured to provide a first initial signal and a second initial signal to the pixel drive circuit, respectively. The first initial signal and the second initial signal may be constant voltage signals, and may have a voltage between the voltage of the first power supply signal provided by the first power supply line VDD and the voltage of the second power supply signal provided by the second power supply line VSS, which is not limited here in the present disclosure.

In an exemplary implementation, the first transistor T1 to the fifth transistor T5 in the pixel drive circuit may be P-type transistors or may be N-type transistors. In some possible exemplary implementations, the first transistor T1 to the fifth transistor T5 in the pixel drive circuit may include P-type transistors and N-type transistors.

In an exemplary implementation, the first transistor T1 to the fifth transistor T5 in the pixel drive circuit may be low-temperature polysilicon transistors, or may be oxide transistors, or may be low-temperature polysilicon transistors and metal oxide transistors. Low Temperature Poly-Silicon (LTPS) is adopted for an active layer of a low temperature polysilicon transistor and a metal oxide semiconductor (Oxide) is adopted for an active layer of an oxide transistor. The low temperature polysilicon transistor has advantages such as a high migration rate and fast charging, and the oxide transistor has advantages such as a low drain current. The low temperature polysilicon transistor and the metal oxide transistor are integrated on one display substrate to form a Low Temperature Polycrystalline Oxide (LTPO for short) display substrate, such that advantages of the low temperature polysilicon transistor and the metal oxide transistor may be utilized, low-frequency drive may be achieved, power consumption may be reduced, and display quality may be improved.

In an exemplary embodiment of the present disclosure, the first transistor T1 to the fifth transistor T5 in the pixel drive circuit may be oxide thin film transistors. The oxide thin film transistor has advantages of a low leakage current and so on. Using a display substrate equipped with an oxide thin film transistor may achieve low frequency driving, reduce power consumption, and improve display quality.

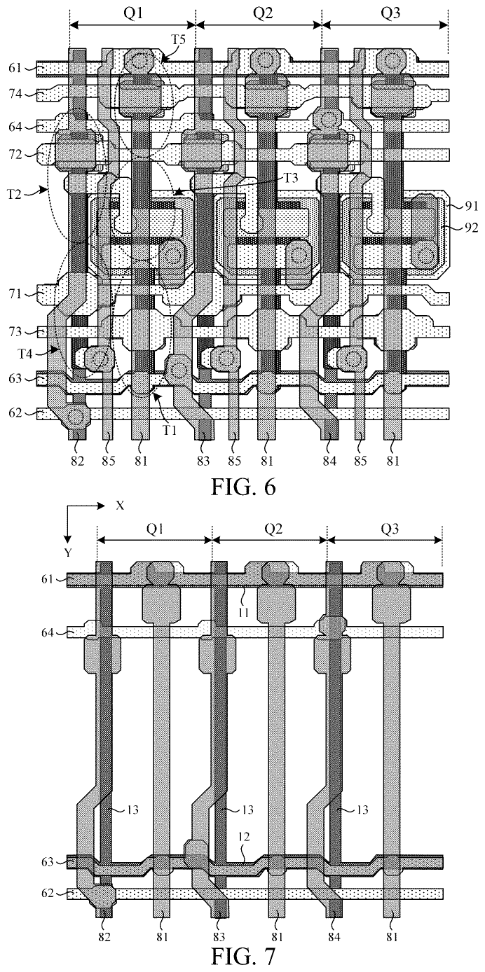

FIG. 6 is a schematic diagram of a planar structure of a display area in a display substrate according to an exemplary embodiment of the present disclosure, illustrating a structure of three circuit units (a first circuit unit Q1, a second circuit unit Q2 and a third circuit unit Q3) in a unit row. On a plane parallel to the display substrate, the display area may include a plurality of circuit units constituting a plurality of unit rows and a plurality of unit columns, and at least one circuit unit may include a pixel drive circuit. As shown in FIG. 6, the pixel drive circuit is connected to a first initial signal line 63, a second initial signal line 64, a first scan signal line 71, a second scan signal line 72, a third scan signal line 73, a light emitting signal line 74, a first power supply line 81 and a data signal line 85. The first scan signal line 71, the second scan signal line 72 and the third scan signal line 73 are configured to provide a scan signal to the pixel drive circuit. The light emitting signal line 74 is configured to provide a light emitting control signal to the pixel drive circuit. The first initial signal line 63 and the second initial signal line 64 are configured to provide a first initial signal and a second initial signal to the pixel drive circuit, respectively. The first power supply line 81 and the data signal line 85 are configured to provide a first power supply signal and a data signal to the pixel drive circuit, respectively.

In an exemplary implementation, the first initial signal line 63, the second initial signal line 64, the first scan signal line 71, the second scan signal line 72, the third scan signal line 73 and the light emitting signal line 74 may be in a shape of a straight line or a bending line whose main body portion extends in a first direction X, and the first power supply line 81 and the data signal line 85 may be in a shape of a straight line or a bending line whose main body portion extends in second direction Y, the first direction X intersecting the second direction Y.

In the present disclosure, “A extends along a B direction” refers to that A may include a main portion and a secondary portion connected to the main portion, wherein the main portion is a line, a line segment, or a strip-shaped body, the main portion extends along the B direction, and a length of the main portion extending along the B direction is greater than a length of the secondary portion extending along another direction. In following description, “A extends along a B direction” means “a main body portion of A extends along a B direction”. In an exemplary implementation, the first direction X may be the unit row direction, and the second direction Y may be the unit column direction.

In an exemplary implementation, the pixel drive circuit may at least include a storage capacitor and a plurality of transistors. The plurality of transistors may include a first transistor T1, a second transistor T2, a third transistor T3, a fourth transistor T4 and a fifth transistor T5. The first transistor T1 to the fifth transistor T5 are used as pixel transistors of the present disclosure. The storage capacitor may include a first electrode plate 91 and a second electrode plate 92 which are stacked, and an orthographic projection of the first electrode plate 91 on a plane of the display substrate overlaps at least partially with an orthographic projection of the second electrode plate 92 on the plane of the display substrate.

In an exemplary implementation, the first transistor T1 to the fifth transistor T5 may be oxide transistors.

In an exemplary implementation, the gate electrode of the first transistor T1 is connected to the third scan signal line 73, the first electrode of the first transistor T1 is connected to the first initial signal line 63, and the first electrode of the first transistor T1 is connected to the second electrode plate 92. The gate electrode of the second transistor T2 is connected to the second scan signal line 72, the first electrode of the second transistor T2 is connected to the second initial signal line 64, and the first electrode of the second transistor T2 is connected to the first electrode plate 91. The gate electrode of the fourth transistor T4 is connected to the first scan signal line 71, the first electrode of the fourth transistor T4 is connected to the data signal line 85, the gate electrode of the fifth transistor T5 is connected to the light emitting signal line 74, and the first electrode of the fifth transistor T5 is connected to the first power supply line 81.

In an exemplary implementation, in a direction perpendicular to the display substrate, the display substrate may at least include a first semiconductor layer arranged on the substrate and a second semiconductor layer arranged on a side of the first semiconductor layer away from the substrate. In at least one circuit unit, one of the first semiconductor layer and the second semiconductor layer may include at least one semiconductor line, and the other may include active layers of the first transistor T1 to the fifth transistor T5.

In an exemplary implementation, the material of the first semiconductor layer may include polysilicon, the material of the second semiconductor layer may include an oxide, at least one semiconductor line may be arranged in the first semiconductor layer, and the active layers of the first transistor T1 to the fifth transistor T5 may be arranged in the second semiconductor layer.

In an exemplary implementation, at least one semiconductor line may be connected to the first power supply line 81, or at least one semiconductor line may be connected to the first initial signal line 63, or at least one semiconductor line may be connected to the second initial signal line 64; and the first power supply line 81, the first initial signal line 63 and the second initial signal line 64 may serve as signal lines transmitting constant voltage signals in the present disclosure.

FIG. 7 is a schematic diagram of a structure of a signal line of a network communication structure according to an exemplary embodiment of the present disclosure. As shown in FIG. 7, in at least one circuit unit, at least one semiconductor line may include a first semiconductor line 11 and a second semiconductor line 12 extending in the first direction X (the pixel row direction), and a third semiconductor line 13 extending in the second direction Y (the pixel column direction), and the first semiconductor line 11 and the second semiconductor line 12 are connected to the third semiconductor line 13 to form a mesh communication structure.

In an exemplary implementation, the first semiconductor line 11 and the second semiconductor line 12 may be arranged on the two sides of the second direction Y in a circuit unit, and the third semiconductor line 13 may be arranged on one side of the first direction X in the circuit unit. The first semiconductor line 11, the second semiconductor line 12 and the third semiconductor line 13 are connected to each other to form an integrated structure and are formed synchronously by a same patterning process.

As shown in FIGS. 6 and 7, at least one circuit unit may further include a first power supply connection line 61 whose main body portion extends in the first direction X, and the first power supply connection line 61 is connected to the first power supply line 81 such that the first power supply connection line 61 extending in the first direction X and the first power supply line 81 extending in the second direction Y form a network communication structure in the display area.

In an exemplary implementation, an orthographic projection of the first power supply connection line 61 on the substrate overlaps at least partially with an orthographic projection of the first semiconductor line 11 on the substrate.

In an exemplary implementation, in a direction perpendicular to the display substrate, the display substrate may further include a plurality of conductive layers, the first power supply connection line 61 and the first power supply line 81 may be arranged in different conductive layers, the first power supply line 81 is connected to the first power supply connection line 61 through a via, and the first power supply connection line 61 is connected to the first semiconductor line 11 through a via.

As shown in FIGS. 6 and 7, at least one circuit unit may further include a second power supply connection line 62 whose main body portion extends in the first direction X and a second power supply line 82 whose main body portion extends in the second direction Y, and the second power supply connection line 62 is connected to the second power supply line 82 such that the second power supply connection line 62 extending in the first direction X and the second power supply line 82 extending in the second direction Y form a network communication structure in the display area.

In an exemplary implementation, an orthographic projection of the second power supply line 82 on the substrate overlaps at least partially with an orthographic projection of the third semiconductor line 13 on the substrate.

In an exemplary implementation, the second power supply connection line 62 and the second power supply line 82 may be arranged in different conductive layers, and the second power supply line 82 may be connected to the second power supply connection line 62 through a via.

As shown in FIGS. 6 and 7, at least one circuit unit may further include a first initial connection line 83 whose main body portion extends in the second direction Y, and the first initial connection line 83 is connected to the first initial signal line 63 such that the first initial signal line 63 extending in the first direction X and the first initial connection line 83 extending in the second direction Y form a network communication structure in the display area.

In an exemplary implementation, an orthographic projection of the first initial connection line 83 on the substrate overlaps at least partially with the orthographic projection of the third semiconductor line 13 on the substrate.

In an exemplary implementation, an orthographic projection of the first initial signal line 63 on the substrate overlaps at least partially with the orthographic projection of the second semiconductor line 12 on the substrate.

In an exemplary implementation, the first initial connection line 83 and the first initial signal line 63 may be arranged in different conductive layers, and the first initial connection line 83 may be connected to the first initial signal line 63 through a via.

As shown in FIGS. 6 and 7, at least one circuit unit may further include a second initial connection line 84 whose main body portion extends in the second direction Y, and the second initial connection line 84 is connected to the second initial signal line 64 such that the second initial signal line 64 extending in the first direction X and the second initial connection line 84 extending in the second direction Y form a network communication structure in the display area.

In an exemplary implementation, an orthographic projection of the second initial connection line 84 on the substrate overlaps at least partially with the orthographic projection of the third semiconductor line 13 on the substrate.

In an exemplary implementation, the second initial connection line 84 and the second initial signal line 64 may be arranged in different conductive layers, and the second initial connection line 84 may be connected to the second initial signal line 64 through a via.

In an exemplary implementation, in a direction perpendicular to the substrate, the display substrate may include a first semiconductor layer, a first conductive layer, a second conductive layer, a second semiconductor layer, a third conductive layer, a fourth conductive layer and a fifth conductive layer arranged on the substrate sequentially in a direction away from the substrate. The first semiconductor line 11, the second semiconductor line 12 and the third semiconductor line 13 may be arranged in the first semiconductor layer; the first electrode plate 91 of the storage capacitor may be arranged in the first conductive layer; the second electrode plate 92 of the storage capacitor may be arranged in the second conductive layer; the top gate electrodes of the plurality of transistors may be arranged in the third conductive layer; the first power supply connection line 61, the second power supply connection line 62, the first initial signal line 63, the second initial signal line 64, the first scan signal line 71, the second scan signal line 72, the third scan signal line 73 and the light emitting signal line 74 may be arranged in the fourth conductive layer; and the first power supply line 81, the second power supply line 82, the first initial connection line 83, the second initial connection line 84 and the data signal line 85 may be arranged in the fifth conductive layer.

Exemplary description is made below through a preparation process of the display substrate according to the exemplary embodiment. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition; coating may be any one or more of spray coating, spin coating, and inkjet printing; and etching may be any one or more of dry etching and wet etching, which is not limited in present disclosure. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are arranged in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

In an exemplary implementation, taking three circuit units (the first circuit unit Q1, the second circuit unit Q2 and the third circuit unit Q3) as an example, the manufacturing process of the display substrate may include the following operations.

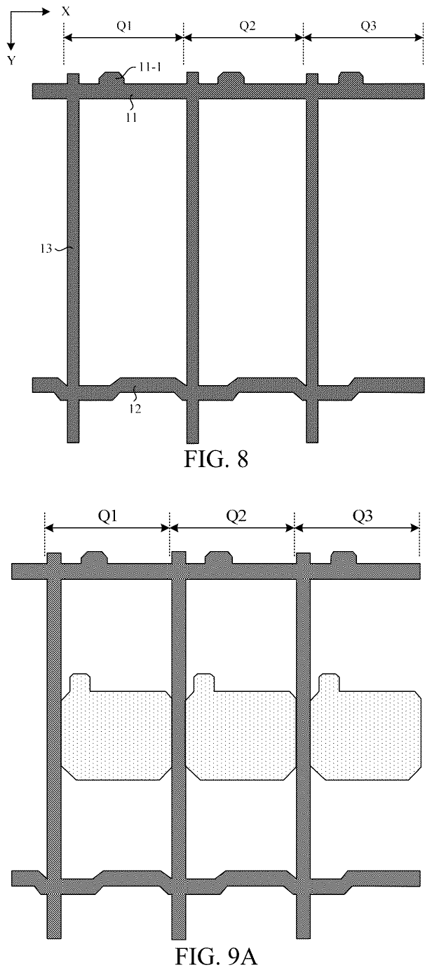

(1) A pattern of a first semiconductor layer is formed. In an exemplary implementation, forming the pattern of the first semiconductor layer may include: sequentially depositing a first insulating thin film and a first semiconductor thin film on a substrate, patterning the first semiconductor thin film by a patterning process to form a first insulating layer disposed on the substrate, and the pattern of the first semiconductor layer disposed on the first insulating layer, as shown in FIG. 8.

In an exemplary implementation, the pattern of the first semiconductor layer of each circuit unit in the display area may at least include a first semiconductor line 11, a second semiconductor line 12 and a third semiconductor line 13.

In an exemplary implementation, the first semiconductor line 11 and the second semiconductor line 12 may be in a shape of a straight line or a bending line whose main body portion extends in the first direction X, the first semiconductor line 11 may be arranged on a side of the circuit unit in an opposite direction of the second direction Y, and the second semiconductor line 12 may be arranged on a side of the circuit unit in the second direction Y.

In an exemplary implementation, a semiconductor block 11-1 may be arranged on the first semiconductor line 11. The semiconductor block 11-1 may be in a shape of a block (e.g. rectangle), and may be arranged on a side of the first semiconductor line 11 away from the second semiconductor line 12, a first end of the semiconductor block 11-1 is connected to the first semiconductor line 11, a second end of the semiconductor block 11-1 extends in a direction away from the second semiconductor line 12, and the semiconductor block 11-1 is configured to be connected to the first power supply connection line formed subsequently.

In an exemplary implementation, the third semiconductor line 13 may be in a shape of a straight line or a bending line whose main body portion extends in the second direction Y, and may be arranged on a side of the circuit unit in the opposite direction of the first direction X and connected to the first semiconductor line 11 and the second semiconductor line 12.

In an exemplary implementation, in at least one circuit unit, the first semiconductor line 11, the second semiconductor line 12 and the third semiconductor line 13 may be connected to each other to form an integrated structure, forming a network communication structure of semiconductor lines.

In an exemplary implementation, the first semiconductor layer may be made of polysilicon (p-Si). In an exemplary implementation, the patterning the first semiconductor thin film through the patterning process may include: forming an amorphous silicon (a-si) thin film on the first insulation thin film, dehydrogenating the amorphous silicon thin film, and crystallizing the dehydrogenated amorphous silicon thin film to form a poly silicon thin film. Subsequently, the poly silicon thin film is patterned to form the pattern of the first semiconductor layer.

In an exemplary implementation, the pattern of the first semiconductor layer in the bezel area of the display substrate may at least include active layers of a plurality of gate transistors, and the first semiconductor line 11, the second semiconductor line 12 and the third semiconductor line 13 in the display area and the active layers of the plurality of gate transistors in the bezel area are arranged in the same layer and are formed synchronously by the same patterning process. In an exemplary implementation, the plurality of gate transistors in the bezel area are polysilicon transistors.

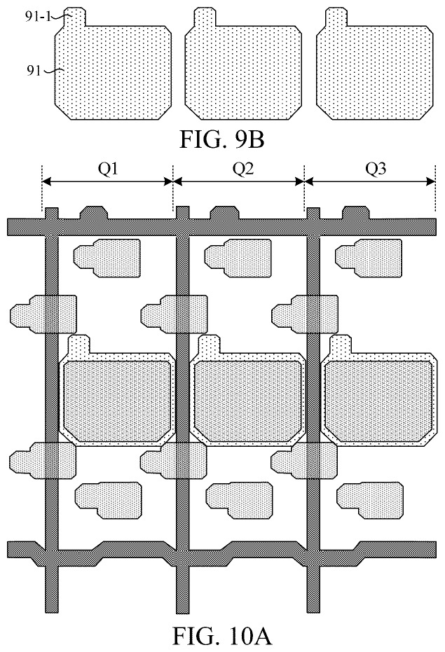

(2) Forming a pattern of a first conductive layer. In an exemplary implementation mode, forming the pattern of the first conductive layer may include: depositing sequentially a second insulation thin film and a first conductive thin film on the substrate on which the aforementioned patterns are formed, and patterning the first conductive thin film through a patterning process to form a second insulating layer that covers the pattern of the first semiconductor layer and form the pattern of the first conductive layer disposed on the second insulating layer, as shown in FIG. 9A and FIG. 9B, and FIG. 9B is a schematic plan view of the first conductive layer in FIG. 9A. In an exemplary implementation, the first conductive layer may be referred to as a first gate metal (GATE1) layer.

In an exemplary implementation, the pattern of the first conductive layer of each circuit unit in the display area may at least include a first electrode plate 91 of the storage capacitor.

In an exemplary implementation, the first electrode plate 91 may be in a shape of a rectangle, corners of the rectangle may be chamfered, and the first electrode plate 91 may be arranged in a middle area of a circuit unit in the first direction X and the second direction Y. In an exemplary implementation, the first electrode plate 91 may serve as a plate of the storage capacitor.

In an exemplary implementation, an orthographic projection of the first electrode plate 91 on the substrate does not overlap with the orthographic projection of the first semiconductor layer on the substrate, i.e., the first electrode plate 91 does not overlap with the first semiconductor line 11, the second semiconductor line 12 and the third semiconductor line 13, which can prevent the first conductive layer and the first semiconductor layer from forming a transistor structure.

In an exemplary implementation, a plate connecting block 91-1 may be arranged on the first electrode plate 91. The plate connecting block 91-1 may be in a shape of a block (e.g. a rectangle) and may be arranged on a side of the first electrode plate 91 away from the second semiconductor line 12. A first end of the plate connecting block 91-1 is connected to the first electrode plate 91, and a second end of the plate connecting block 91-1 extends in a direction away from the second semiconductor line 12. The plate connecting block 91-1 is configured to be connected to the second connection electrode formed subsequently.

In an exemplary implementation, in at least one circuit unit, the first electrode plate 91 and the plate connecting block 91-1 may be connected to each other to form an integrated structure.

In an exemplary implementation, the pattern of the first conductive layer of the bezel area in the display substrate may at least include gate electrodes of a plurality of gate transistors. After the pattern of the first conductive layer is formed, the first conductive layer may be used as a shield to conduct a conductivity treatment on the first semiconductor layer, the first semiconductor layer shielded by the gate electrode in the bezel area forms a channel region, and the first semiconductor layer not shielded by the gate electrode is made to be conductive. Since none of the first semiconductor line 11, the second semiconductor line 12 and the third semiconductor line 13 in the display area is shielded by the first electrode plate 91, the first semiconductor line 11, the second semiconductor line 12 and the third semiconductor line 13 in the display area are all made to be conductive.

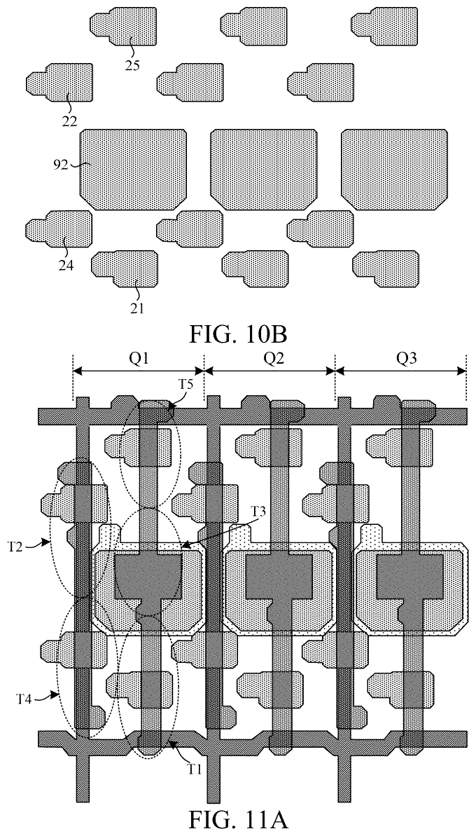

(3) A pattern of a second conductive layer is formed. In an exemplary implementation, forming a pattern of a second conductive layer may include: depositing sequentially a third insulation thin film and a second conductive thin film on the substrate on which the aforementioned patterns are formed, and the second conductive thin film is patterned through a patterning process to form a third insulating layer that covers the first conductive layer and the pattern of the second conductive layer provided on the third insulating layer, as shown in FIG. 10A and FIG. 10B. FIG. 10B is a planar schematic diagram of the second conductive layer in FIG. 10A. In an exemplary implementation, the second conductive layer may be referred to as a second gate metal (GATE2) layer.

In an exemplary implementation, the pattern of the second conductive layer of each circuit unit in the display area at least includes: a first bottom gate electrode 21, a second bottom gate electrode 22, a fourth bottom gate electrode 24, a fifth bottom gate electrode 25, and a second electrode plate 92 of the storage capacitor.

In an exemplary implementation, a profile of second electrode plate 92 may be in a shape of a rectangle, a chamfer may be provided at a corner of the rectangle, an orthographic projection of the second electrode plate 92 on the base substrate is at least overlapped with an orthographic projection of the first electrode plate 91 on the base substrate, the second electrode plate 92 may serve as anther plate of the storage capacitor, and the first electrode plate 91 and the second electrode plate 92 form the storage capacitor of the pixel drive circuit.

In an exemplary implementation, an orthographic projection of the second electrode plate 92 on the substrate does not overlap with the orthographic projection of the first semiconductor layer on the substrate, i.e., the second electrode plate 92 does not overlap with the first semiconductor line 11, the second semiconductor line 12 and the third semiconductor line 13, which may prevent the second conductive layer and the first semiconductor layer from forming parasitic capacitance.

In an exemplary implementation, the second electrode plate 92 may also serve as a shielding electrode of the third transistor T3 to shield the channel region of the third transistor T3 to block light emitted by the light emitting device and reflected light of the film layers from irradiating the channel region of the third transistor T3 and prevent the oxide transistor from characteristic drift due to illumination, thus improving electrical characteristics of the third oxide transistor T3.

In an exemplary implementation, the first bottom gate electrode 21 may be in a shape of a strip extending in the first direction X and may be located on a side of the second electrode plate 92 in the second direction Y. The first bottom gate electrode 21 may serve as a bottom gate electrode of the first transistor T1, and may also serve as a shielding electrode of the first transistor T1 to shield the channel region of the first transistor T1 to block light emitted by the light emitting device and reflected light of the film layers from irradiating the channel region of the first transistor T1 and prevent the oxide transistor from characteristic drift due to illumination, thus improving electrical characteristics of the first oxide transistor T1.

In an exemplary implementation, the second bottom gate electrode 22 may be in a shape of a strip extending in the first direction X and may be located on a side of the second electrode plate 92 in the opposite direction of the second direction Y. The second bottom gate electrode 22 may serve as a bottom gate electrode of the second transistor T2, and may also serve as a shielding electrode of the second transistor T2 to shield the channel region of the second transistor T2 to block light emitted by the light emitting device and reflected light of the film layers from irradiating the channel region of the second transistor T2 and prevent the oxide transistor from characteristic drift due to illumination, thus improving electrical characteristics of the second oxide transistor T2.

In an exemplary implementation, the fourth bottom gate electrode 24 may be in a shape of a strip extending in the first direction X and may be located between the first bottom gate electrode 21 and the second electrode plate 92. The fourth bottom gate electrode 24 may serve as a bottom gate electrode of the fourth transistor T4, and may also serve as a shielding electrode of the fourth transistor T4 to shield the channel region of the fourth transistor T4 to block light emitted by the light emitting device and reflected light of the film layers from irradiating the channel region the fourth transistor T4 and prevent the oxide transistor from characteristic drift due to illumination, thus improving electrical characteristics of the fourth oxide transistor T4.

In an exemplary implementation, the fifth bottom gate electrode 25 may be in a shape of a strip extending in the first direction X and may be located on a side of the second bottom gate electrode 22 away from the second electrode plate 92. The fifth bottom gate electrode 25 may serve as a bottom gate electrode of the fifth transistor T5, and may also serve as a shielding electrode of the fifth transistor T5 to shield the channel region of the fifth transistor T5 to block light emitted by the light emitting device and reflected light of the film layers from irradiating the channel region of the fifth transistor T5 and prevent the oxide transistor from characteristic drift due to illumination, thus improving electrical characteristics of the fifth oxide transistor T5.

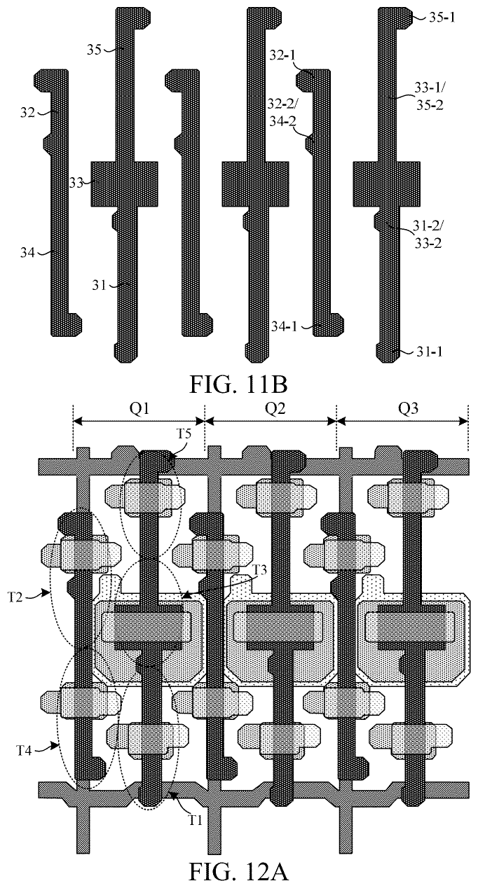

(4) Forming a pattern of a second semiconductor layer. In an exemplary implementation, forming the pattern of the second semiconductor layer may include: sequentially depositing a fourth insulating thin film and a second semiconductor thin film on the substrate on which the aforementioned patterns are formed, patterning the second semiconductor thin film through a patterning process to form a fourth insulating layer covering the second conductive layer, and the pattern of the second semiconductor layer disposed on the fourth insulating layer, as shown in FIGS. 11A and 11B, FIG. 11B is a schematic planar view of the second semiconductor layer in FIG. 11A.

In an exemplary implementation, the pattern of the second semiconductor layer of each circuit unit in the display area may at least include the first active layer 31 of the first transistor T1 to the fifth active layer 35 of the fifth transistor T5, the first active layer 31, the third active layer 33 and the fifth active layer 35 are connected to each other to form an integrated structure, and the second active layer 32 and the fourth active layer 34 are connected to each other to form an integrated structure.

In an exemplary implementation, in the first direction X, the second active layer 32 and the fourth active layer 34 which are of an integrated structure may be located on a side of the third active layer 33 in the opposite direction of the first direction X. In the second direction Y, the second active layer 32 and the fifth active layer 35 may be located on a side of the third active layer 33 in the opposite direction of the second direction Y, and the first active layer 31 and the fourth active layer 34 may be located on a side of the third active layer 33 in the second direction Y.

In an exemplary implementation, the first active layer 31, the second active layer 32, the fourth active layer 34 and the fifth active layer 35 may be in a shape of a strip extending in the second direction Y, and the third active layer 33 may be in a shape of a rectangle.

In an exemplary implementation, an orthographic projection of the first active layer 31 on the substrate overlaps at least partially with an orthographic projection of the first bottom gate electrode 21 on the substrate, an orthographic projection of the second active layer 32 on the substrate overlaps at least partially with an orthographic projection of the second bottom gate electrode 22 on the substrate, an orthographic projection of the third active layer 33 on the substrate overlaps at least partially with an orthographic projection of the second electrode plate 92 on the substrate, an orthographic projection of the fourth active layer 34 on the substrate overlaps at least partially with an orthographic projection of the fourth bottom gate electrode 24 on the substrate, and an orthographic projection of the fifth active layer 35 on the substrate overlaps at least partially with an orthographic projection of the fifth bottom gate electrode 25 on the substrate.

In an exemplary implementation, orthographic projections of the second active layer 32 and the fourth active layer 34 which are of an integrated structure on the substrate overlap at least partially with the orthographic projection of the third semiconductor line 13 on the substrate. The third semiconductor line 13 may play a role of shielding to block light from irradiating the second transistor T2 and the fourth transistor T4 and prevent the oxide transistor from characteristic drift due to illumination, thus improving electrical characteristics of the oxide transistor.

In an exemplary implementation, an active layer of each transistor may include a first region, a second region, and a channel region located between the first region and the second region. In an exemplary implementation, a second region 31-2 of the first active layer may serve as a second region 33-2 of the third active layer, i.e., the second region 31-2 of the first active layer and the second region 33-2 of the third active layer may be connected to each other. A first region 33-1 of the third active layer may serve as a first region 35-1 of the fifth active layer, i.e., the first region 33-1 of the third active layer and the first region 35-1 of the fifth active layer may be connected to each other. A second region 32-2 of the second active layer may serve as a second region 34-2 of the fourth active layer, i.e., the second region 32-2 of the second active layer and the second region 34-2 of the fourth active layer may be connected to each other. A first region 31-1 of the first active layer, a first region 32-1 of the second active layer, a first region 34-1 of the fourth active layer and the first region 35-1 of the fifth active layer may be arranged separately.

In an exemplary implementation, an orthographic projection of the first region 31-1 of the first active layer on the substrate overlaps at least partially with an orthographic projection of the second semiconductor line 12 on the substrate, and an orthographic projection of the first region 35-1 of the fifth active layer on the substrate overlaps at least partially with an orthographic projection of the first semiconductor line 11 on the substrate. The first semiconductor line 11 and the second semiconductor line 12 may play a role of shielding to prevent the oxide transistor from characteristic drift due to illumination, thus improving electrical characteristics of the oxide transistor.

In an exemplary implementation, the second semiconductor layer may be made of an oxide, and the first transistor T1 to the fifth transistor T5 are all oxide transistors. In an exemplary implementation, the second semiconductor thin film may be made of Indium Gallium Zinc Oxide (IGZO), wherein electron mobility of the Indium Gallium Zinc Oxide (IGZO) is higher than that of amorphous silicon.

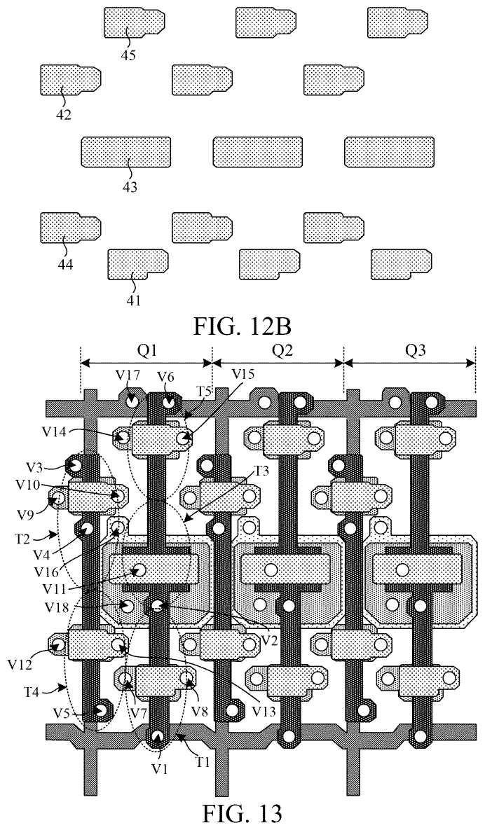

(5) A pattern of a third conductive layer is formed. In an exemplary implementation, forming the pattern of the third conductive layer may include: depositing a fifth insulating thin film and a third conductive thin film sequentially on the substrate on which the aforementioned patterns are formed, and patterning the third conductive thin film through a patterning process to form a fifth insulating layer covering the second semiconductor layer and the pattern of the third conductive layer disposed on the fifth insulating layer, as shown in FIGS. 12A and 12B, FIG. 12B being a schematic plan view of the third conductive layer in FIG. 12A. In an exemplary implementation, the third conductive layer may be referred to as a third gate metal (GATE3) layer.

In an exemplary implementation, the pattern of the third conductive layer of each circuit unit in the display area at least includes: a first top gate electrode 41, a second top gate electrode 42, a third gate electrode 43, a fourth top gate electrode 44 and a fifth top gate electrode 45.

In an exemplary implementation, the first top gate electrode 41 may be in a shape of a strip extending in the first direction X and may be located on a side of the second electrode plate 92 in the second direction Y, an orthographic projection of the first top gate electrode 41 on the substrate overlaps at least partially with the orthographic projection of the first active layer on the substrate, and the first top gate electrode 41 may serve as the top gate electrode of the first transistor T1. In an exemplary implementation, the orthographic projection of the first top gate electrode 41 on the substrate overlaps at least partially with the orthographic projection of the first bottom gate electrode 21 on the substrate, and the first bottom gate electrode 21 and the first top gate electrode 41 form the first transistor T1 of a bottom-gate top-gate structure.

In an exemplary implementation, the second top gate electrode 42 may be in a shape of a strip extending in the first direction X and may be located on a side of the second electrode plate 92 in the opposite direction of the second direction Y, an orthographic projection of the second top gate electrode 42 on the substrate overlaps at least partially with the orthographic projection of the second active layer on the substrate, and the second top gate electrode 42 may serve as the top gate electrode of the second transistor T2. In an exemplary implementation, the orthographic projection of the second top gate electrode 42 on the substrate overlaps at least partially with the orthographic projection of the second bottom gate electrode 22 on the substrate, and the second bottom gate electrode 22 and the second top gate electrode 42 form the second transistor T2 of a bottom-gate top-gate structure.

In an exemplary implementation, the third gate electrode 43 may be in a shape of a strip extending in the first direction X and may be located in the area where the second electrode plate 92 is located, an orthographic projection of the third gate electrode 43 on the substrate overlaps at least partially with the orthographic projection of the third active layer on the substrate, and the third gate electrode 43 may serve as the gate electrode of the third transistor T3.

In an exemplary implementation, the fourth top gate electrode 44 may be in a shape of a strip extending in the first direction X and may be located between the first top gate electrode 41 and the second electrode plate 92, an orthographic projection of the fourth top gate electrode 44 on the substrate overlaps at least partially with the orthographic projection of the fourth active layer on the substrate, and the fourth top gate electrode 44 may serve as the top gate electrode of the fourth transistor T4. In an exemplary implementation, the orthographic projection of the fourth top gate electrode 44 on the substrate overlaps at least partially with the orthographic projection of the fourth bottom gate electrode 24 on the substrate, and the fourth bottom gate electrode 24 and the fourth top gate electrode 44 form the fourth transistor T4 of a bottom-gate top-gate structure.

In an exemplary implementation, the fifth top gate electrode 45 may be in a shape of a strip extending in the first direction X and may be located on a side of the second top gate electrode 42 away from the second electrode plate 92, an orthographic projection of the fifth top gate electrode 45 on the substrate overlaps at least partially with the orthographic projection of the fifth active layer on the substrate, and the fifth top gate electrode 45 may serve as the top gate electrode of the fifth transistor T5. In an exemplary implementation, the orthographic projection of the fifth top gate electrode 45 on the substrate overlaps at least partially with the orthographic projection of the fifth bottom gate electrode 25 on the substrate, and the fifth bottom gate electrode 25 and the fifth top gate electrode 45 form the fifth transistor T5 of a bottom-gate top-gate structure.

(6) A pattern of a sixth insulating layer is formed. In an exemplary implementation mode, forming the pattern of the sixth insulating layer may include: depositing a sixth insulating thin film on the substrate on which the aforementioned patterns are formed, patterning the fifth insulating thin film using a patterning process to form a sixth insulating layer covering the third conductive layer, wherein a plurality of vias are provided on the sixth insulating layer, as shown in FIG. 13.

In an exemplary implementation, a plurality of vias of each circuit unit in the display area at least include: a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16, a seventeenth via V17 and an eighteenth via V18.

In an exemplary implementation, an orthographic projection of the first via V1 on the substrate is within the range of the orthographic projection of the first region of the first active layer on the substrate, the sixth insulating layer and the fifth insulating layer within the first via V1 are etched away to expose a surface of the first region of the first active layer, and the first via V1 is configured such that the first initial signal line formed subsequently is connected to the first region of the first active layer through the via.

In an exemplary implementation, an orthographic projection of the second via V2 on the substrate is within the range of the orthographic projection of the second region of the first active layer (which is also the second region of the third active layer) on the substrate, the sixth insulating layer and the fifth insulating layer within the second via V2 are etched away to expose a surface of the second region of the first active layer (which is also the second region of the third active layer), and the second via V2 is configured such that the first connection electrode formed subsequently is connected to the second region of the first active layer (which is also the second region of the third active layer) through the via.

In an exemplary implementation, an orthographic projection of the third via V3 on the substrate is within the range of the orthographic projection of the first region of the second active layer on the substrate, the sixth insulating layer and the fifth insulating layer within the third via V3 are etched away to expose a surface of the first region of the second active layer, and the third via V3 is configured such that the second initial signal line formed subsequently is connected to the first region of the second active layer through the via.

In an exemplary implementation, an orthographic projection of the fourth via V4 on the substrate is within the range of the orthographic projection of the second region of the second active layer (which is also the second region of the fourth active layer) on the substrate, the sixth insulating layer and the fifth insulating layer within the fourth via V4 are etched away to expose a surface of the second region of the second active layer (which is also the second region of the fourth active layer), and the fourth via V4 is configured such that the second connection electrode formed subsequently is connected to the second region of the second active layer (which is also the second region of the fourth active layer) through the via.

In an exemplary implementation, an orthographic projection of the fifth via V5 on the substrate is within the range of the orthographic projection of the first region of the fourth active layer on the substrate, the sixth insulating layer and the fifth insulating layer within the fifth via V5 are etched away to expose a surface of the first region of the fourth active layer, and the fifth via V5 is configured such that the third connection electrode formed subsequently is connected to the first region of the fourth active layer through the via.

In an exemplary implementation, an orthographic projection of the sixth via V6 on the substrate is within the range of the orthographic projection of the first region of the fifth active layer on the substrate, the sixth insulating layer and the fifth insulating layer within the sixth via V6 are etched away to expose a surface of the first region of the fifth active layer, and the sixth via V6 is configured such that the first power supply connection line formed subsequently is connected to the first region of the fifth active layer through the via.

In an exemplary implementation, an orthographic projection of the seventh via V7 on the substrate is within the range of the orthographic projection of the first bottom gate electrode 21 on the substrate, the sixth insulating layer, the fifth insulating layer and the fourth insulating layer within the seventh via V7 are etched away to expose a surface of the first bottom gate electrode 21, and the seventh via V7 is configured such that the third scan signal line formed subsequently is connected to the first bottom gate electrode 21 through the via.

In an exemplary implementation, an orthographic projection of the eighth via V8 on the substrate is within the range of the orthographic projection of the first top gate electrode 41 on the substrate, the sixth insulating layer within the eighth via V8 is etched away to expose a surface of the first top gate electrode 41, and the eighth via V8 is configured such that the third scan signal line formed subsequently is connected to the first top gate electrode 41 through the via.

In an exemplary implementation, an orthographic projection of the ninth via V9 on the substrate is within the range of the orthographic projection of the second bottom gate electrode 22 on the substrate, the sixth insulating layer, the fifth insulating layer and the fourth insulating layer within the ninth via V9 are etched away to expose a surface of the second bottom gate electrode 22, and the ninth via V9 is configured such that the second scan signal line formed subsequently is connected to the second bottom gate electrode 22 through the via.

In an exemplary implementation, an orthographic projection of the tenth via V10 on the substrate is within the range of the orthographic projection of the second top gate electrode 42 on the substrate, the sixth insulating layer within the tenth via V10 is etched away to expose a surface of the second top gate electrode 42, and the tenth via V10 is configured such that the second scan signal line formed subsequently is connected to the second top gate electrode 42 through the via.

In an exemplary implementation, an orthographic projection of the eleventh via V11 on the substrate is within the range of the orthographic projection of the third gate electrode 43 on the substrate, the sixth insulating layer within the eleventh via V11 is etched away to expose a surface of the third gate electrode 43, and the eleventh via V11 is configured such that the second connection electrode formed subsequently is connected to the third gate electrode 43 through the via.

In an exemplary implementation, an orthographic projection of the twelfth via V12 on the substrate is within the range of the orthographic projection of the fourth bottom gate electrode 24 on the substrate, the sixth insulating layer, the fifth insulating layer and the fourth insulating layer within the twelfth via V12 are etched away to expose a surface of the fourth bottom gate electrode 24, and the twelfth via V12 is configured such that the first scan signal line formed subsequently is connected to the fourth bottom gate electrode 24 through the via.

In an exemplary implementation, an orthographic projection of the thirteenth via V13 on the substrate is within the range of the orthographic projection of the fourth top gate electrode 44 on the substrate, the sixth insulating layer within the thirteenth via V13 is etched away to expose a surface of the fourth top gate electrode 44, and the thirteenth via V13 is configured such that the first scan signal line formed subsequently is connected to the fourth top gate electrode 44 through the via.

In an exemplary implementation, an orthographic projection of the fourteenth via V14 on the substrate is within the range of the orthographic projection of the fifth bottom gate electrode 25 on the substrate, the sixth insulating layer, the fifth insulating layer and the fourth insulating layer within the fourteenth via V14 are etched away to expose a surface of the fifth bottom gate electrode 25, and the fourteenth via V14 is configured such that the light emitting signal line formed subsequently is connected to the fifth bottom gate electrode 25 through the via.

In an exemplary implementation, an orthographic projection of the fifteenth via V15 on the substrate is within the range of the orthographic projection of the fifth top gate electrode 45 on the substrate, the sixth insulating layer within the fifteenth via V15 is etched away to expose a surface of the fifth top gate electrode 45, and the fifteenth via V15 is configured such that the light emitting signal line formed subsequently is connected to the fifth top gate electrode 45 through the via.

In an exemplary implementation, an orthographic projection of the sixteenth via V16 on the substrate is within the range of the orthographic projection of the plate connecting block 91-1 on the first electrode plate 91 on the substrate, the sixth insulating layer, the fifth insulating layer, the fourth insulating layer and the third insulating layer within the sixteenth via V16 are etched away to expose a surface of the plate connecting block 91-1, and the sixteenth via V16 is configured such that the second connection electrode formed subsequently is connected to the plate connecting block 91-1 through the via.

In an exemplary implementation, an orthographic projection of the seventeenth via V17 on the substrate is within the range of the orthographic projection of the semiconductor block 11-1 on the first semiconductor line 11 on the substrate, the sixth insulating layer, the fifth insulating layer, the fourth insulating layer, the third insulating layer and the second insulating layer within the seventeenth via V17 are etched away to expose a surface of the semiconductor block 11-1, and the seventeenth via V17 is configured such that the first power supply connection line formed subsequently is connected to the semiconductor block 11-1 through the via.

In an exemplary implementation, an orthographic projection of the eighteenth via V18 on the substrate is within the range of the orthographic projection of the second electrode plate 92 on the substrate, the sixth insulating layer, the fifth insulating layer and the fourth insulating layer within the eighteenth via V18 are etched away to expose a surface of the second electrode plate 92, and the eighteenth via V18 is configured such that the first connection electrode formed subsequently is connected to the second electrode plate 92 through the via.

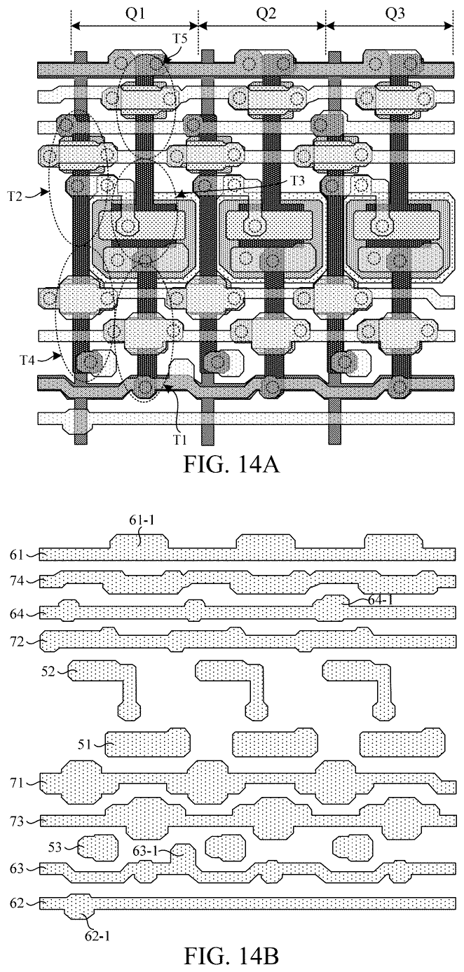

(7) A pattern of a fourth conductive layer is formed. In an exemplary implementation mode, forming the pattern of the fourth conductive layer may include: depositing a fourth conductive thin film on the substrate on which the aforementioned patterns are formed, and patterning the fourth conductive thin film through a patterning process to form the fourth conductive layer disposed on the sixth insulating layer, as shown in FIG. 14A and FIG. 14B, and FIG. 14B is a schematic plan view of the fourth conductive layer in FIG. 14A. In an exemplary implementation, the fourth conductive layer may be referred to as a first source drain metal (SD1) layer.

In an exemplary implementation, the fourth conductive layer of each circuit unit in the display area at least includes: a first connection electrode 51, a second connection electrode 52, a third connection electrode 53, a first power supply connection line 61, a second power supply connection line 62, a first initial signal line 63, a second initial signal line 64, a first scan signal line 71, a second scan signal line 72, a third scan signal line 73 and a light emitting signal line 74.

In an exemplary implementation, the first connection electrode 51 may be in a shape of a strip extending in the first direction X, and the first connection electrode 51 is connected to the second region of the first active layer (which is also the second region of the third active layer) through the second via V2 on the one hand, and to the second electrode plate 92 through the eighteenth via V18 on the other hand. In an exemplary implementation, the first connection electrode 51 causes the second electrode of the first transistor T1, the second electrode of the third transistor T3 and the second electrode plate 92 of the storage capacitor to have the same potential, the first connection electrode 51 may serve as the third node N3 of the pixel drive circuit, and the first connection electrode 51 is configured to be connected to the anode connection electrode formed subsequently.

In an exemplary implementation, the second connection electrode 52 may be in a shape of L, a first end of the second connection electrode 52 is connected to the second region of the second active layer (which is also the second region of the fourth active layer) through the fourth via V4, a second end of the second connection electrode 52 is connected to the third gate electrode 43 through the eleventh via V11, and a portion between the first end and the second end of the second connection electrode 52 is connected to the plate connecting block 91-1 through the sixteenth via V16. Since the plate connecting block 91-1 is connected to the first electrode plate 91 and the third gate electrode 43 serves as the gate electrode of the third transistor T3, the second connection electrode 52 realizes the connection between the second electrode of the second transistor T2, the second electrode of the fourth transistor T4, the gate electrode of the third transistor T3, and the first electrode plate 91 of the storage capacitor, and the second connection electrode 52 can serve as the first node N1 of the pixel drive circuit.

In an exemplary implementation, the third connection electrode 53 may be in a shape of a block (e.g., a rectangle), the third connection electrode 53 is connected to the first region of the fourth active layer through the fifth via V5, and the third connection electrode 53 is configured to be connected to the data signal line formed subsequently.

In an exemplary implementation, the first power supply connection line 61 may be in a shape of a straight line or a bending line whose main body portion extends in the first direction X, and may be arranged on a side of the circuit unit in the opposite direction of the second direction Y. The first power supply connection line 61 is connected to the first region of the fifth active layer through the sixth via V6 on the one hand, and to the semiconductor block 11-1 through the seventeenth via V17 on the other hand. Since the first power supply connection line 61 is configured to be connected to the first power supply line formed subsequently, it can be realized that the first power supply line writes a first power supply signal to the first electrode of the fifth transistor T5. Since the semiconductor block 11-1 is connected to the first semiconductor line 11, and the first semiconductor line 11, the second semiconductor line 12 and the third semiconductor line 13 are connected to each other, a network communication structure for transmitting the first power supply signal is formed in the first semiconductor layer of the display area, which is conducive to improving the uniformity of the panel, avoiding poor display of the display substrate, and ensuring the display effect of the display substrate.

In an exemplary implementation, an orthographic projection of the first power supply connection line 61 on the substrate overlaps at least partially with the orthographic projection of the first semiconductor line 11 in the first semiconductor layer on the substrate.

In an exemplary implementation, a first power supply connection block 61-1 may be arranged on the first power supply connection line 61. The first power supply connection block 61-1 may be in a shape of a block (e.g., a rectangle) and may be arranged on a side of the first power supply connection line 61 away from the second electrode plate 92, a first end of the first power supply connection block 61-1 is connected to the first power supply connection line 61, a second end of the first power supply connection block 61-1 extends in a direction away from the second electrode plate 92, and the first power supply connection block 61-1 is configured to be connected to the first power supply line formed subsequently.

In an exemplary implementation, the second power supply connection line 62 may be in a shape of a straight line or a bending line whose main body portion extends in the first direction X, and may be arranged on a side of the circuit unit in the second direction Y.

In an exemplary implementation, a second power supply connection block 62-1 may be arranged on the second power supply connection line 62. The second power supply connection line 62 may be in a shape of a block (e.g., a rectangle) and may be arranged at least on a side of the second power supply connection line 62 away from the second electrode plate 92, a first end of the second power supply connection block 62-1 is connected to the second power supply connection line 62, a second end of the second power supply connection block 62-1 extends in a direction away from the second electrode plate 92, and the second power supply connection block 62-1 is configured to be connected to the second power supply line formed subsequently. In an exemplary implementation, in a unit column, only one second power supply connection block 62-1 may be arranged for every three circuit units. For example, the second power supply connection block 62-1 may be arranged on a side of the first circuit unit Q1 in the opposite direction of the first direction X.

In an exemplary implementation, the first initial signal line 63 may be in a shape of a straight line or a bending line whose main body portion extends in the first direction X, and may be arranged between the second power supply connection line 62 and the second electrode plate 92, and the first initial signal line 63 is connected to the first region of the first active layer through the first via V1; thus it can be realized that the first initial signal line 63 writes a first initial signal to the first electrode of the first transistor T1.

In an exemplary implementation, an orthographic projection of the first initial signal line 63 on the substrate overlaps at least partially with the orthographic projection of the second semiconductor line 12 in the first semiconductor layer on the substrate.

In an exemplary implementation, a first initial connection block 63-1 may be arranged on the first initial signal line 63. The first initial connection block 63-1 may be in a shape of a block (e.g., a rectangle) and may be arranged at least on a side of the first initial signal line 63 close to the second electrode plate 92, a first end of the first initial connection block 63-1 is connected to the first initial signal line 63, a second end of the first initial connection block 63-1 extends in a direction close to the second electrode plate 92, and the first initial connection block 63-1 is configured to be connected to the first initial connection line formed subsequently. In an exemplary implementation, in a unit column, only one first initial connection block 63-1 may be arranged for every three circuit units. For example, the first initial connection block 63-1 may be arranged on a side of the first circuit unit Q1 in the first direction X.

In an exemplary implementation, the second initial signal line 64 may be in a shape of a straight line or a bending line whose main body portion extends in the first direction X, and may be arranged between the first power supply connection line 61 and the second electrode plate 92, and the second initial signal line 64 is connected to the first region of the second active layer through the third via V3; thus it can be realized that the second initial signal line 64 writes a second initial signal to the first electrode of the second transistor T2.

In an exemplary implementation, a second initial connection block 64-1 may be arranged on the second initial signal line 64. The second initial connection block 64-1 may be in a shape of a block (e.g., a rectangle) and may be arranged at least on a side of the second initial signal line 64 away from the second electrode plate 92, a first end of the second initial connection block 64-1 is connected to the second initial signal line 64, a second end of the second initial connection block 64-1 extends in a direction away from the second electrode plate 92, and the second initial connection block 64-1 is configured to be connected to the second initial connection line formed subsequently. In an exemplary implementation, in a unit column, only one second initial connection block 64-1 may be arranged for every three circuit units. For example, the first initial connection block 63-1 may be arranged on a side of the second circuit unit Q2 in the first direction X.

In an exemplary implementation, the first scan signal line 71 may be in a shape of a straight line or a bending line whose main body portion extends in the first direction X, and may be arranged between the first initial signal line 63 and the second electrode plate 92. The first scan signal line 71 is connected to the fourth bottom gate electrode 24 through the twelfth via V12 on the one hand, and to the fourth top gate electrode 44 through the thirteenth via V13 on the other hand. The fourth bottom gate electrode 24 and the fourth top gate electrode 44 serve as the bottom gate electrode and the top gate electrode of the fourth transistor T4, respectively, and the first scan signal line 71 is connected to the fourth bottom gate electrode 24 and the fourth top gate electrode 44 at the same time, thus enabling the first scan signal line 71 to control turn-on and turn-off of the fourth transistor T4.

In an exemplary implementation, the second scan signal line 72 may be in a shape of a straight line or a bending line whose main body portion extends in the first direction X, and may be arranged between the second initial signal line 64 and the second electrode plate 92. The second scan signal line 72 is connected to the second bottom gate electrode 22 through the ninth via V9 on the one hand, and to the second top gate electrode 42 through the tenth via V10 on the other hand. The second bottom gate electrode 22 and the second top gate electrode 42 serve as the bottom gate electrode and the top gate electrode of the second transistor T2, respectively, and the second scan signal line 72 is connected to the second bottom gate electrode 22 and the second top gate electrode 42 at the same time, thus enabling the second scan signal line 72 to control turn-on and turn-off of the second transistor T2.

In an exemplary implementation, the third scan signal line 73 may be in a shape of a straight line or a bending line whose main body portion extends in the first direction X, and may be arranged between the first initial signal line 63 and the first scan signal line 71, and the third scan signal line 73 is connected to the first bottom gate electrode 21 through the seventh via V7 on the one hand, and to the first top gate electrode 41 through the eighth via V8 on the other hand. The first bottom gate electrode 21 and the first top gate electrode 41 serve as the bottom gate electrode and the top gate electrode of the first transistor T1, respectively, and the third scan signal line 73 is connected to the first bottom gate electrode 21 and the first top gate electrode 41 at the same time, thus enabling the third scan signal line 73 to control turn-on and turn-off of the first transistor T1.

In an exemplary implementation, the light emitting signal line 74 may be in a shape of a straight line or a bending line whose main body portion extends in the first direction X, and may be arranged between the first power supply connection line 61 and the second initial signal line 64. The light emitting signal line 74 is connected to the fifth bottom gate electrode 25 through the fourteenth via V14 on the one hand, and to the fifth top gate electrode 45 through the fifteenth via V15 on the other hand. The fifth bottom gate electrode 25 and the fifth top gate electrode 45 serve as the bottom gate electrode and the top gate electrode of the fifth transistor T5, respectively, and the light emitting signal line 74 is connected to the fifth bottom gate electrode 25 and the fifth top gate electrode 45 at the same time, thus enabling the light emitting signal line 74 to control turn-on and turn-off of the fifth transistor T5.

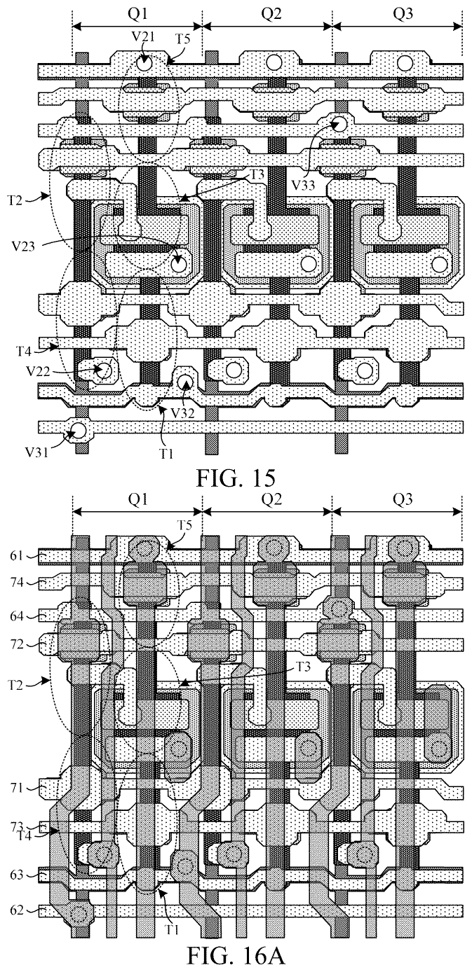

(8) A pattern of a first planarization layer is formed. In an exemplary implementation mode, forming the pattern of the first planarization layer may include: coating a first planarization thin film on the substrate on which the aforementioned patterns are formed, patterning the first planarization thin film using a patterning process to form a first planarization layer covering the pattern of the fourth conductive layer, wherein the first planarization layer is provided with a plurality of vias, as shown in FIG. 15.

In an exemplary implementation, a plurality of vias in each circuit unit in the display area at least include a twenty-first via V21, a twenty-second via V22 and a twenty-third via V23.

In an exemplary implementation, an orthographic projection of the twenty-first via V21 on the substrate is within the range of the orthographic projection of the first power supply connection block 61-1 on the first power supply connection line 61 on the substrate, the first planarization layer within the twenty-first via V21 is etched away to expose a surface of the first power supply connection block 61-1, and the twenty-first via V21 is configured such that the first power supply line formed subsequently is connected to the first power supply connection block 61-1 through the via.

In an exemplary implementation, an orthographic projection of the twenty-second via V22 on the substrate is within the range of the orthographic projection of the third connection electrode 53 on the substrate, the first planarization layer within the twenty-second via V22 is etched away to expose a surface of the third connection electrode 53, and the twenty-second via V22 is configured such that the data signal line formed subsequently is connected to the third connection electrode 53 through the via.

In an exemplary implementation, an orthographic projection of the twenty-third via V23 on the substrate is within the range of the orthographic projection of the first connection electrode 51 on the substrate, the first planarization layer within the twenty-third via V23 is etched away to expose a surface of the first connection electrode 51, and the twenty-third via V23 is configured such that the anode connection electrode formed subsequently is connected to the first connection electrode 51 through the via.

In an exemplary implementation, the plurality of vias in the display area may further include a thirty-first via V31, a thirty-second via V32 and a thirty-third via V33.

In an exemplary implementation, an orthographic projection of the thirty-first via V31 on the substrate is within the range of the orthographic projection of the second power supply connection block 62-1 on the second power supply connection line 62 on the substrate, the first planarization layer within the thirty-first via V31 is etched away to expose a surface of the second power supply connection block 62-1, and the thirty-first via V31 is configured such that the second power supply line formed subsequently is connected to the second power supply connection block 62-1 through the via. In an exemplary implementation, in a unit column, only one thirty-first via V31 may be arranged for every three circuit units.

In an exemplary implementation, an orthographic projection of the thirty-second via V32 on the substrate is within the range of the orthographic projection of the first initial connection block 63-1 on the first initial signal line 63 on the substrate, the first planarization layer within the thirty-second via V32 is etched away to expose a surface of the first initial connection block 63-1, and the thirty-second via V32 is configured such that the first initial connection line formed subsequently is connected to the first initial connection block 63-1 through the via. In an exemplary implementation, in a unit column, only one thirty-second via V32 may be arranged for every three circuit units.

In an exemplary implementation, an orthographic projection of the thirty-third via V33 on the substrate is within the range of the orthographic projection of the second initial connection block 64-1 on the second initial signal line 64 on the substrate, the first planarization layer within the thirty-third via V33 is etched away to expose a surface of the second initial connection block 64-1, and the thirty-third via V33 is configured such that the second initial connection line formed subsequently is connected to the second initial connection block 64-1 through the via. In an exemplary implementation, in a unit column, only one thirty-third via V33 may be arranged for every three circuit units.

(9) A pattern of a fifth conductive layer is formed. In an exemplary implementation mode, forming the pattern of the fifth conductive layer may include: depositing a fifth conductive thin film on the substrate on which the above-mentioned patterns are formed, and patterning the fifth conductive thin film using a patterning process to form the fifth conductive layer disposed on the first planarization layer, as shown in FIG. 16A and FIG. 16B, and FIG. 16B is a schematic plan view of the fifth conductive layer in FIG. 16A. In an exemplary implementation, the fifth conductive layer may be referred to as a second source-drain metal (SD2) layer.

In an exemplary implementation, the fifth conductive layer of each circuit unit in the display area at least includes a first power supply line 81, a data signal line 85 and an anode connection electrode 86.

In an exemplary implementation, the first power supply line 81 may be in a shape of a straight line or a bending line extending in the second direction Y, and the first power supply line 81 is connected to the first power supply connection block 61-1 through the twenty-first via V21. Since the first power supply connection block 61-1 is connected to the first power supply connection line 61, connection between the first power supply line 81 and the first power supply connection line 61 is realized, and the first power supply connection line 61 whose main body portion extends in the first direction X and the first power supply line 81 whose main body portion extends in the second direction Y constitute a first power supply line of a network communication structure in the display area, which can reduce the resistance of the first power supply line to the greatest extent and reduce the voltage drop of the first power supply signal, thus effectively improving the uniformity of the first power supply signal in the display substrate, effectively improving the uniformity of display, and improving the display quality.

In an exemplary implementation, a first shielding block 81-1 is connected on the first power supply line 81, and an orthographic projection of the first shielding block 81-1 on the substrate overlaps at least partially with the orthographic projections of the fifth bottom gate electrode 25 and the fifth top gate electrode 45 on the substrate. The first shielding block 81-1 can shield the fifth transistor T5 to reduce the influence of other signals in the pixel drive circuit on the fifth transistor T5, thereby improving the working stability of the fifth transistor T5.

In an exemplary implementation, the orthographic projection of the first power supply line 81 on the substrate overlaps at least partially with the orthographic projection of the first active layer on the substrate, and the first power supply line 81 can shield the first transistor T1 to reduce the influence of light on the electrical characteristics of the first transistor T1, thereby improving the working stability of the first transistor T1.

In an exemplary implementation, the orthographic projection of the first power supply line 81 on the substrate overlaps at least partially with the orthographic projection of the third active layer on the substrate, and the first power supply line 81 can shield the third transistor T3 to reduce the influence of light on the electrical characteristics of the third transistor T3, thereby improving the working stability of the third transistor T3.

In an exemplary implementation, the orthographic projection of the first power supply line 81 on the substrate overlaps at least partially with the orthographic projection of the fifth active layer on the substrate, and the first power supply line 81 can shield the fifth transistor T5 to reduce the influence of light on the electrical characteristics of the fifth transistor T5, thereby improving the working stability of the fifth transistor T5.

In an exemplary implementation, the data signal line 85 may be in a shape of a straight line or a bending line extending in the second direction Y, and the data signal line 85 is connected to the third connection electrode 53 through the twenty-second via V22. Since the third connection electrode 53 is connected to the first region of the fourth active layer, connection of the data signal line 85 to the first electrode of the fourth transistor T4 is realized, and the data signal line 85 can write a data signal to the first electrode of the fourth transistor T4.

In an exemplary implementation, the anode connection electrode 86 may be in a shape of a strip extending in the second direction Y, the anode connection electrode 86 is connected to the first connection electrode 51 through the twenty-third via V23, and the anode connection electrode 86 is configured to be connected to the anode formed subsequently. Since the first connection electrode 51 is connected to the second region of the first active layer (which is also the second region of the third active layer), connection of the anode formed subsequently to the second electrode of the first transistor T1 and the second electrode of the third transistor T3 is realized. The pixel drive circuit can drive a light emitting device to emit light.

In an exemplary implementation, the fifth conductive layer of the display area may also include a second power supply line 82, a first initial connection line 83 and a second initial connection line 84.

In an exemplary implementation, the second power supply line 82 may be in a shape of a straight line or a bending line extending in the second direction Y, and the second power supply line 82 is connected to the second power supply connection block 62-1 through the thirty-first via V31. Since the second power supply connection block 62-1 is connected to the second power supply connection line 62, connection between the second power supply line 82 and the second power supply connection line 62 is realized, and the second power supply connection line 62 whose main body portion extends in the first direction X and the second power supply line 82 whose main body portion extends in the second direction Y form a second power supply line of a network communication structure in the display area, which can reduce the resistance of the second power supply line to the greatest extent and reduce the voltage drop of the second power supply signal, thus effectively improving the uniformity of the second power supply signal in the display substrate, effectively improving the uniformity of display, and improving the display quality.

In an exemplary implementation, in at least one unit column, a second shielding block 82-1 is connected on the second power supply line 82, and an orthographic projection of the second shielding block 82-1 on the substrate overlaps at least partially with the orthographic projections of the second bottom gate electrode 22 and the second top gate electrode 42 on the substrate. The second shielding block 82-1 can shield the second transistor T2 to reduce the influence of other signals in the pixel drive circuit on the second transistor T2, thereby improving the working stability of the second transistor T2.

In an exemplary implementation, in a unit row, only one second power supply line 82 may be arranged for every three circuit units. For example, the second power supply line 82 may be arranged in the first circuit unit Q1.

In an exemplary implementation, in at least one unit column, the orthographic projection of the second power supply line 82 on the substrate overlaps at least partially with the orthographic projection of the second active layer on the substrate, and the second power supply line 82 can shield the second transistor T2 to reduce the influence of light on the electrical characteristics of the second transistor T2, thereby improving the working stability of the second transistor T2.

In an exemplary implementation, in at least one unit column, the orthographic projection of the second power supply line 82 on the substrate overlaps at least partially with the orthographic projection of the fourth active layer on the substrate, and the second power supply line 82 can shield the fourth transistor T4 to reduce the influence of light on the electrical characteristics of the fourth transistor T4, thereby improving the working stability of the fourth transistor T4.

In an exemplary implementation, in at least one unit column, the orthographic projection of the second power supply line 82 on the substrate overlaps at least partially with the orthographic projection of the third semiconductor line 13 in the first semiconductor layer on the substrate.

In an exemplary implementation, the first initial connection line 83 may be in a shape of a straight line or a bending line extending in the second direction Y, and the first initial connection line 83 is connected to the first initial connection block 63-1 through the thirty-second via V32. Since the first initial connection block 63-1 is connected to the first initial signal line 63, connection between the first initial signal line 63 and the first initial connection line 83 is realized, and the first initial signal line 63 whose main body portion extends in the first direction X and the first initial connection line 83 whose main body portion extends in the second direction Y constitute a first initial signal line of a network communication structure in the display area, which can reduce the resistance of the first initial signal line to the greatest extent and reduce the voltage drop of the first initial signal, thus effectively improving the uniformity of the first initial signal in the display substrate, effectively improving the uniformity of display, and improving the display quality.

In an exemplary implementation, in at least one unit column, a third shielding block 83-1 is connected on the first initial connection line 83, and an orthographic projection of the third shielding block 83-1 on the substrate overlaps at least partially with the orthographic projections of the second bottom gate electrode 22 and the second top gate electrode 42 on the substrate. The third shielding block 83-1 can shield the second transistor T2 to reduce the influence of other signals in the pixel drive circuit on the second transistor T2, thereby improving the working stability of the second transistor T2.

In an exemplary implementation, in a unit row, only one first initial connection line 83 may be arranged for every three circuit units. For example, the first initial connection line 83 may be arranged in the second circuit unit Q2.

In an exemplary implementation, in at least one unit column, an orthographic projection of the first initial connection line 83 on the substrate overlaps at least partially with the orthographic projection of the second active layer on the substrate, and the first initial connection line 83 can shield the second transistor T2 to reduce the influence of light on the electrical characteristics of the second transistor T2, thereby improving the working stability of the second transistor T2.

In an exemplary implementation, in at least one unit column, the orthographic projection of the first initial connection line 83 on the substrate overlaps at least partially with the orthographic projection of the fourth active layer on the substrate, and the first initial connection line 83 can shield the fourth transistor T4 to reduce the influence of light on the electrical characteristics of the fourth transistor T4, thereby improving the working stability of the fourth transistor T4.

In an exemplary implementation, in at least one unit column, the orthographic projection of the first initial connection line 83 on the substrate overlaps at least partially with the orthographic projection of the third semiconductor line 13 in the first semiconductor layer on the substrate.

In an exemplary implementation, the second initial connection line 84 may be in a shape of a straight line or a bending line extending in the second direction Y, and the second initial connection line 84 is connected to the second initial connection block 64-1 through the thirty-third via V33. Since the second initial connection block 64-1 is connected to the second initial signal line 64, connection between the second initial signal line 64 and the second initial connection line 84 is realized, and the second initial signal line 64 whose main body portion extends in the first direction X and the second initial connection line 84 whose main body portion extends in the second direction Y constitute a second initial signal line of a network communication structure in the display area, which can reduce the resistance of the second initial signal line to the greatest extent and reduce the voltage drop of the second initial signal, thus effectively improving the uniformity of the first initial signal in the display substrate, effectively improving the uniformity of display, and improving the display quality.

In an exemplary implementation, in at least one unit column, a fourth shielding block 84-1 is connected on the second initial connection line 84, and an orthographic projection of the fourth shielding block 84-1 on the substrate overlaps at least partially with the orthographic projections of the second bottom gate electrode 22 and the second top gate electrode 42 on the substrate. The fourth shielding block 84-1 can shield the second transistor T2 to reduce the influence of other signals in the pixel drive circuit on the second transistor T2, thereby improving the working stability of the second transistor T2.

In an exemplary implementation, in a unit row, only one second initial connection line 84 may be arranged for every three circuit units. For example, the second initial connection line 84 may be arranged in the third circuit unit Q2.

In an exemplary implementation, in at least one unit column, an orthographic projection of the second initial connection line 84 on the substrate overlaps at least partially with the orthographic projection of the second active layer on the substrate, and the second initial connection line 84 can shield the second transistor T2 to reduce the influence of light on the electrical characteristics of the second transistor T2, thereby improving the working stability of the second transistor T2.

In an exemplary implementation, in at least one unit column, the orthographic projection of the second initial connection line 84 on the substrate overlaps at least partially with the orthographic projection of the fourth active layer on the substrate, and the second initial connection line 84 can shield the fourth transistor T4 to reduce the influence of light on the electrical characteristics of the fourth transistor T4, thereby improving the working stability of the fourth transistor T4.

In an exemplary implementation, in at least one unit column, the orthographic projection of the second initial connection line 84 on the substrate overlaps at least partially with the orthographic projection of the third semiconductor line 13 in the first semiconductor layer on the substrate.

In an exemplary implementation, the first power supply line 81, the second power supply line 82, the first initial connection line 83, the second initial connection line 84 and the data signal line 85 may be bending lines with unequal widths, which may not only facilitate the layout of the pixel structure, but also reduce the parasitic capacitance between the signal lines.

(10) A pattern of a second planarization layer is formed. In an exemplary implementation, forming the pattern of the second planarization layer may include: coating a second planarization thin film on the substrate on which the aforementioned patterns are formed, and patterning the second planarization thin film through a patterning process to form a second planarization layer covering the pattern of the fifth conductive layer. The second planarization layer is at least provided with an anode via. An orthographic projection of the anode via on the substrate is within the range of the orthographic projection of the anode connection electrode 86 on the substrate, and the second planarization layer within the anode via is etched away to expose a surface of the anode connection electrode 86. The anode via is configured such that the anode formed subsequently is connected to the anode connection electrode 86 through the via.

So far, the drive structure layer has been prepared on the substrate. In a plane parallel to the display substrate, the drive structure layer may include a plurality of circuit units, each of which may include a pixel drive circuit, and a first scan signal line, a second scan signal line, a third scan signal line, a light emitting signal line, a data signal line, a first power supply line, a first initial signal line, and a second initial signal line connected to the pixel drive circuit. In a plane perpendicular to the display substrate, the drive structure layer may include a first insulating layer, a first semiconductor layer, a second insulating layer, a first conductive layer, a third insulating layer, a second conductive layer, a fourth insulating layer, a second semiconductor layer, a fifth insulating layer, a third conductive layer, a sixth insulating layer, a fourth conductive layer, a first planarization layer, a fifth conductive layer and a second planarization layer which are arranged sequentially on the substrate. The first semiconductor layer may at least include semiconductor lines of a network communication structure; the first conductive layer may at least include a first electrode plate of a storage capacitor; the second conductive layer may at least include a second electrode plate of the storage capacitor and bottom gate electrodes of a plurality of transistors; the second semiconductor layer may at least include active layers of the plurality of transistors; the third conductive layer may at least include top gate electrodes of the plurality of transistors; the fourth conductive layer may at least include a first power supply connection line, a second power supply connection line, a first initial signal line, a second initial signal line, a first scan signal line, a second scan signal line, a third scan signal line, a light emitting signal line and a plurality of connection electrodes; and the fifth conductive layer may at least include a first power supply line, a second power supply line, a data signal line, a first initial connection line, a second initial connection line and an anode connection electrode.

In an exemplary implementation, the substrate may be a flexible substrate, or a rigid substrate. The rigid substrate may include, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In an exemplary implementation mode, the flexible substrate may include a first flexible material layer, a first inorganic material layer, a semiconductor layer, a second flexible material layer, and a second inorganic material layer which are stacked. Materials of the first flexible material layer and the second flexible material layer may be Polyimide (PI), Polyethylene Terephthalate (PET), or a surface-treated polymer soft film, etc., and materials of the first inorganic material layer and the second inorganic material layer may be Silicon Nitride (SiNx), Silicon Oxide (SiOx), or the like, for improving water and oxygen resistance of the substrate. The first inorganic material layer and the second inorganic material layer may also be referred to as barrier layers, and a material of the semiconductor layer may be amorphous silicon (a-si).

In an exemplary implementation, the first conductive layer, the second conductive layer, the third conductive layer, the fourth conductive layer, and the fifth conductive layer may be made of a metal material, such as any one or more of Argentum (Ag), Copper (Cu), Aluminum (Al), and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Mo/Cu/Mo. The first insulating layer, the second insulating layer, the third insulating layer, the fourth insulating layer, the fifth insulating layer, and the sixth insulating layer may be made of any one or more of Silicon Oxide (SiOx), Silicon Nitride (SiNx), and Silicon OxyNitride (SiON), and may be a single layer, multiple layers, or a composite layer. The first planarization layer and the second planarization layer may be made of an organic material, such as resin.

In an exemplary implementation, after the drive structure layer has been prepared, a light emitting structure layer may be prepared on the drive structure layer first, and then an encapsulation structure layer may be prepared on the light emitting structure layer, which will not be described further here.

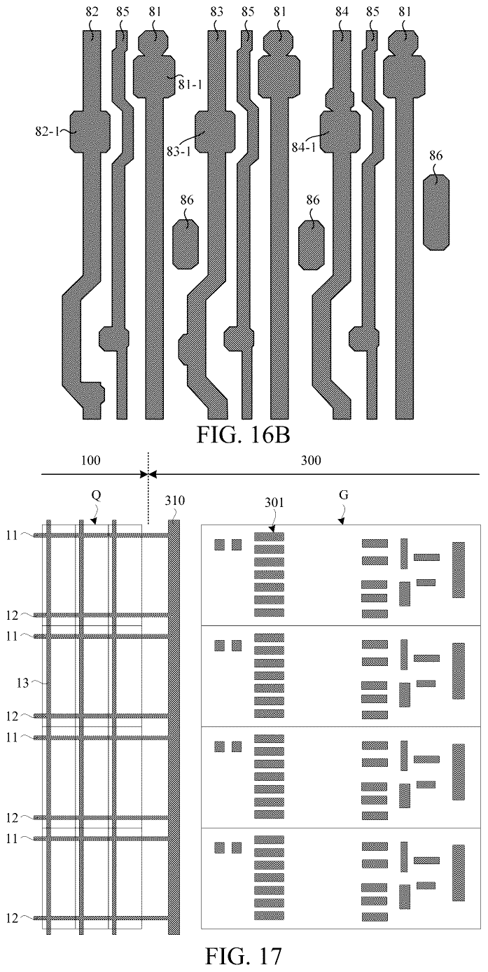

FIG. 17 is a schematic diagram of a semiconductor wire in a bezel area according to an exemplary embodiment of the present disclosure, illustrating a structure of a first semiconductor layer in region A in FIG. 2. As shown in FIG. 17, in a direction parallel to the display substrate, the display substrate may include a display area 100 and a bezel area 300 located on at least one side of the display area 100. The display area 100 may at least include a plurality of circuit units Q constituting a plurality of unit rows and a plurality of unit columns, and the bezel area 300 may at least include a plurality of gate units G extending in a direction parallel to a display area edge. The display area edge is an edge on a side of the display area close to the bezel area. In a direction perpendicular to the display substrate, the display substrate at least includes a first semiconductor layer, the first semiconductor layer of the display area 100 may at least include a semiconductor line arranged in the circuit unit Q, and the first semiconductor layer of the bezel area 300 may at least include a plurality of gate active layers arranged in the gate unit G, and at least one semiconductor wire arranged between the circuit unit Q and the gate unit G. The semiconductor line in the display area 100, the plurality of gate active layers in the bezel area 300 and the at least one semiconductor wire in the bezel area 300 are arranged in the same layer, made of the same material, and formed synchronously by the same patterning process.

In an exemplary implementation, the semiconductor lines arranged in the circuit unit Q may at least include a first semiconductor line 11, a second semiconductor line 12 and a third semiconductor line 13 that form a network communication structure. In a unit row, the first semiconductor lines 11 of the plurality of circuit units are connected sequentially to form an integrated structure, and the second semiconductor lines 12 of the plurality of circuit units are connected sequentially to form an integrated structure. In a unit column, the third semiconductor lines 13 of the plurality of circuit units are connected sequentially to form an integrated structure.

In an exemplary implementation, the plurality of gate active layers 301 arranged in the gate unit G may serve as active layers of a plurality of gate transistors, and the plurality of gate transistors form a gate drive circuit with a capacitor.

In an exemplary implementation, the semiconductor wire 310 arranged between the circuit unit Q and the gate unit G may be in a shape of a straight line or a bending line extending in the direction parallel to the display area edge, and the semiconductor wire 310 is connected to the first semiconductor lines 11 and the second semiconductor lines 12 of a plurality of unit rows in the display area 100.

In an exemplary implementation, there may be one or a plurality of semiconductor wires 310 in the bezel area 300, and the plurality of semiconductor wires 310 may be connected to each other.

In an exemplary implementation, the first semiconductor lines 11 and the second semiconductor lines 12 of a plurality of unit rows in the display area 100 and the semiconductor wire 310 in the bezel area 300 may be connected to each other to form an integrated structure.

In an exemplary implementation, in a direction parallel to the display substrate, the circuit unit Q has a first unit area and the gate unit G has a second unit area. In at least one circuit unit Q, orthographic projections of the first semiconductor line 11, the second semiconductor line 12 and the third semiconductor line 13 on the substrate have a first area, and in at least one gate unit G, orthographic projections of the plurality of gate active layers 301 on the substrate have a second area. The ratio of the first area to the first unit area has a first ratio value, and the ratio of the second area to the second unit area has a second ratio value. The ratio of the first ratio value to the second ratio value may be about 0.9 to 1.1. For example, the ratio of the first ratio value to the second ratio value may be about 1.0.

In an exemplary implementation, the first ratio value may be about 0.1 to 0.2. For example, the first ratio value may be about 0.15, i.e., the proportion of the polysilicon layer in the display area is about 0.15.

In an exemplary implementation, the second ratio value may be about 0.1 to 0.2. For example, the second ratio value may be about 0.15, i.e., the proportion of the polysilicon layer in the bezel area is about 0.15.

As can be seen from the structure and preparation process of the display substrate described above, in the display substrate provided in an exemplary embodiment of the present disclosure, by arranging semiconductor lines in the first semiconductor layer in the display area and connecting the semiconductor lines to the first power supply line to form a mesh communication structure for transmitting the first power supply signal in the first semiconductor layer, the resistance of the first power supply line can be effectively reduced, the voltage drop of the first power supply signal can be reduced, thus effectively improving the uniformity of the first power supply signal in the display substrate, effectively improving the uniformity of display, and improving the display quality.

In a display substrate, an oxide transistor is used in the pixel drive circuit in the display area, and a polysilicon transistor is used in a gate drive circuit in the bezel area, so that a polysilicon layer is provided in the bezel area, while no polysilicon layer is provided in the display area, which results in defects such as uneven etching of the polysilicon layer. In the present disclosure, by arranging semiconductor lines in the polysilicon layer of the display area, the defects such as uneven etching of the polysilicon layer in the existing display substrates can be effectively avoided, which improves the yield of the display substrate. In the present disclosure, by setting the proportion of the polysilicon layer in the display area to be similar to the proportion of the polysilicon layer in the bezel area, the etching uniformity of the polysilicon layer can be further improved, thus improving the yield of the display substrate to the greatest extent.

In the present disclosure, by arranging a semiconductor lead in the polysilicon layer of the bezel area and connecting the semiconductor lead to the semiconductor lines of the display area to connect the plurality of semiconductor lines of the display area outside the display area, static electricity in the display area can be effectively eliminated and the process quality and product yield can be improved.

In the present disclosure, a first power supply connection line extending in the first direction X and a first power supply line extending in the second direction Y are arranged in the display area to form another mesh communication structure for transmitting the first power supply signal in the display area, i.e., in the present disclosure, the display area is provided with two network communication structures for transmitting the first power supply signal and the two network communication structures are connected to each other, which can further reduce the resistance of the first power supply line, further reduce the voltage drop of the first power supply signal, further improve the uniformity of the first power supply signal in the display substrate, further improve the uniformity of display, and improve the display quality to the greatest extent.

In the present disclosure, a first initial signal line extending in the first direction X and a first initial connection line extending in the second direction Y are arranged in the display area to form a first initial signal line of a network communication structure in the display area, which can effectively reduce the resistance of the first initial signal line and reduce the voltage drop of the first initial signal, thus effectively improving the uniformity of the first initial signal in the display substrate, effectively improving the uniformity of display, and improving the display quality.

In the present disclosure, a second initial signal line extending in the first direction X and a second initial connection line extending in the second direction Y are arranged in the display area to form a second initial signal line of a network communication structure in the display area, which can effectively reduce the resistance of the second initial signal line and reduce the voltage drop of the second initial signal, thus effectively improving the uniformity of the second initial signal in the display substrate, effectively improving the uniformity of display, and improving the display quality.

In the present disclosure, a second power supply connection line extending in the first direction X and a second power supply line extending in the second direction Y are arranged in the display area, which not only realizes the structure of VSS in pixel, but also can effectively reduce the resistance of the second power supply line and reduce the voltage drop of the second power supply signal, thus effectively improving the uniformity of the second power supply signal in the display substrate, effectively improving the uniformity of display, and improving the display quality. In addition, the structure of VSS in pixel can greatly reduce the width of a bezel power lead in the bezel area, which is conducive to achieving a narrow bezel.

In the present disclosure, the first power supply connection line overlaps at least partially with the first semiconductor line, the first initial signal line overlaps at least partially with the second semiconductor line, and the second power supply line, the first initial connection line and the second initial connection line overlap at least partially with the third semiconductor line, which can effectively improve the stability of the signal voltage in each signal line and improve the working performance of the pixel drive circuit.

The manufacturing process in the present disclosure may be compatible well with an existing manufacturing process, is simple in process implementation, is easy to implement, and has a high production efficiency, a low production cost, and a high yield.

The structure shown and mentioned above in the present disclosure and the manufacturing process therefor are merely an exemplary description. In an exemplary implementation, the corresponding structures may be altered and the patterning processes may be added or reduced according to actual needs. For example, a polysilicon transistor is used in the pixel drive circuit, an oxide transistor is used in the gate drive circuit, and the semiconductor lines may be arranged in an oxide layer. As another example, the semiconductor lines may be connected to the first initial signal line, the second initial signal line, or the second power supply line, which is not limited here in the present disclosure.

In an exemplary implementation, the display substrate in the present disclosure may be applied to other display devices having pixel drive circuits, such as quantum dot displays and the like, which is not limited in the present disclosure.

The present disclosure also provides a manufacturing method for a display substrate, for preparing the display substrate according to the foregoing embodiments. In an exemplary implementation, the display substrate includes a display area, the display area includes a plurality of circuit units constituting a plurality of unit rows and a plurality of unit columns, at least one circuit unit includes a pixel drive circuit and at least one signal line transmitting a constant voltage signal, the pixel drive circuit includes at least one pixel transistor; the method may include:

forming a first semiconductor layer on a substrate and a second semiconductor layer arranged on a side of the first semiconductor layer away from the substrate, wherein in at least one circuit unit, one of the first semiconductor layer and the second semiconductor layer includes at least one semiconductor line, and the other includes an active layer of the pixel transistor, and the semiconductor line is connected to the signal line.

The present disclosure also provides a display apparatus which includes the aforementioned display substrate. The display apparatus may be any product or component with a display function, such as a mobile phone, a tablet computer, a television, a display, a laptop computer, a digital photo frame, or a navigator, which is not limited in the embodiments of the present invention.

Although implementations disclosed in the present disclosure are as above, it should be noted that the above implementations are exemplary only rather than restrictive. Therefore, the present disclosure is not limited to what is specifically shown and described herein. Various modifications, substitutions or omissions may be made in forms and details of implementation modes without departing from the scope of the present disclosure.

1. A display substrate, comprising a display area, wherein
the display area comprises a plurality of circuit units constituting a plurality of unit rows and a plurality of unit columns, at least one circuit unit comprises a pixel drive circuit and at least one signal line transmitting a constant voltage signal, the pixel drive circuit comprises at least one pixel transistor;
in a direction perpendicular to the display substrate, the display substrate at least comprises a first semiconductor layer arranged on a substrate and a second semiconductor layer arranged on a side of the first semiconductor layer away from the substrate; and
in at least one circuit unit, one of the first semiconductor layer and the second semiconductor layer comprises at least one semiconductor line, and the other comprises an active layer of the pixel transistor, and the semiconductor line is connected to the signal line.

2. The display substrate according to claim 1, wherein
in at least one circuit unit, the at least one semiconductor line comprises a first semiconductor line and a second semiconductor line extending in a pixel row direction, and a third semiconductor line extending in a pixel column direction, and
the first semiconductor line and the second semiconductor line are connected to the third semiconductor line to form a mesh communication structure.

3. The display substrate according to claim 2, wherein
in at least one circuit unit, the at least one signal line comprises a first power supply connection line extending in the pixel row direction and a first power supply line extending in the pixel column direction,
the first power supply connection line is connected to the first power supply line to form a mesh communication structure, and
the first power supply connection line is connected to the first semiconductor line.

4. The display substrate according to claim 3, wherein an orthographic projection of the first power supply connection line on the substrate overlaps at least partially with an orthographic projection of the first semiconductor line on the substrate.

5. The display substrate according to claim 3, wherein
in a direction perpendicular to the display substrate, the display substrate further comprises a plurality of conductive layers,
the first power supply connection line and the first power supply line are arranged in different conductive layers,
the first power supply line is connected to the first power supply connection line through a via, and
the first power supply connection line is connected to the first semiconductor line through a via.

6. The display substrate according to claim 2, wherein
in at least one circuit unit, the at least one signal line comprises a second power supply connection line extending in the pixel row direction and a second power supply line extending in the pixel column direction, the second power supply connection line is connected to the second power supply line to form a mesh communication structure; and
an orthographic projection of the second power supply line on the substrate overlaps at least partially with an orthographic projection of the third semiconductor line on the substrate.

7. The display substrate according to claim 2, wherein
in at least one circuit unit, the at least one signal line comprises a first initial signal line extending in the pixel row direction and a first initial connection line extending in the pixel column direction, the first initial connection line is connected to the first initial signal line to form a mesh communication structure; and
an orthographic projection of the first initial connection line on the substrate overlaps at least partially with the orthographic projection of the third semiconductor line on the substrate.

8. The display substrate according to claim 7, wherein an orthographic projection of the first initial signal line on the substrate overlaps at least partially with an orthographic projection of the second semiconductor line on the substrate.

9. The display substrate according to claim 2, wherein
in at least one circuit unit, the at least one signal line comprises a second initial signal line extending in the pixel row direction and a second initial connection line extending in the pixel column direction, the second initial connection line is connected to the second initial signal line to form a mesh communication structure; and
an orthographic projection of the second initial connection line on the substrate overlaps at least partially with the orthographic projection of the third semiconductor line on the substrate.

10. The display substrate according to claim 1, wherein
the pixel drive circuit further comprises a storage capacitor comprising a first electrode plate and a second electrode plate,
an orthographic projection of the first electrode plate on the substrate overlaps at least partially with an orthographic projection of the second electrode plate on the substrate,
the orthographic projection of the first electrode plate on the substrate does not overlap with an orthographic projection of the semiconductor line on the substrate, and
the orthographic projection of the second electrode plate on the substrate does not overlap with the orthographic projection of the semiconductor line on the substrate.

11. The display substrate according to claim 1, wherein
a material of the first semiconductor layer comprises polysilicon, a material of the second semiconductor layer comprises an oxide,
the first semiconductor layer comprises the semiconductor lines, and
the second semiconductor layer comprises the active layer of the pixel transistor.

12. The display substrate according to claim 1, wherein
the display substrate further comprises a bezel area arranged on at least one side of the display area,
the bezel area comprises a plurality of gate units,
at least one gate unit comprises a gate drive circuit comprising a plurality of gate transistors, and
active layers of the gate transistors and the semiconductor lines are arranged in a same layer and made of a same material.

13. The display substrate according to claim 12, wherein
in a direction parallel to the display substrate, the circuit unit has a first unit area,
in at least one circuit unit, an orthographic projection of the semiconductor line on the substrate has a first area, and
a ratio of the first area to the first unit area has a first ratio value which is 0.1 to 0.2.

14. The display substrate according to claim 13, wherein
in a direction parallel to the display substrate, the gate unit has a second unit area,
in at least one gate unit, orthographic projections of the active layers of the plurality of gate transistors on the substrate have a second area,
a ratio of the second area to the second unit area has a second ratio value, and
a ratio of the first ratio value to the second ratio value is 0.9 to 1.1.

15. The display substrate according to claim 12, wherein
the bezel area further comprises a semiconductor lead extending in a direction of a display area edge and connected to the semiconductor lines in a plurality of unit rows, and
the display area edge is an edge of the display area close to the bezel area.

16. The display substrate according to claim 15, wherein the semiconductor lead and the semiconductor line are arranged in a same layer and are connected to each other to form an integrated structure.

17. A display apparatus, comprising the display substrate according to claim 1.

18. A method for manufacturing a display substrate, wherein the display substrate comprises a display area, the display area comprises a plurality of circuit units constituting a plurality of unit rows and a plurality of unit columns, at least one circuit unit comprises a pixel drive circuit and at least one signal line transmitting a constant voltage signal, the pixel drive circuit comprises at least one pixel transistor; the method comprising:
forming a first semiconductor layer on a substrate and a second semiconductor layer arranged on a side of the first semiconductor layer away from the substrate, wherein in at least one circuit unit, one of the first semiconductor layer and the second semiconductor layer comprises at least one semiconductor line, and the other comprises an active layer of the pixel transistor, and the semiconductor line is connected to the signal line.

19. The display substrate according to claim 2, wherein
the display substrate further comprises a bezel area arranged on at least one side of the display area,
the bezel area comprises a plurality of gate units,
at least one gate unit comprises a gate drive circuit comprising a plurality of gate transistors, and
active layers of the gate transistors and the semiconductor lines are arranged in a same layer and made of a same material.

20. The display substrate according to claim 3, wherein
the display substrate further comprises a bezel area arranged on at least one side of the display area,
the bezel area comprises a plurality of gate units,
at least one gate unit comprises a gate drive circuit comprising a plurality of gate transistors, and
active layers of the gate transistors and the semiconductor lines are arranged in a same layer and made of a same material.
